(19) United States
(12) Patent Application Publication
(10) Pub. No.: US 2013/0214301 A1
(43) Pub. Date: Aug. 22, 2013

(54) DISPLAY APPARATUS AND METHOD FOR MANUFACTURING DISPLAY APPARATUS

(71) Applicant: Sony Corporation, (US)

(72) Inventors: Jiro Yamada, Kanagawa (JP); Hiroyuki Kiso, Miyagi (JP); Chiyoko Sato, Kanagawa (JP)

(73) Assignee: SONY CORPORATION, Tokyo (JP)

(21) Appl. No.: 13/753,055

(22) Filed: Jan. 29, 2013

(30) Foreign Application Priority Data
Feb. 17, 2012 (JP) 2012-033053

(51) Int. Cl. H01L 33/08; H01L 33/60

(52) U.S. Cl. CPC H01L 33/08; H01L 33/60
USPC 257/88; 438/31

(57) ABSTRACT

A display device is provided including a plurality of light emitting devices formed on a substrate, a plurality of first members corresponding to the light emitting devices and formed directly on a portion of the respective light emitting device, and a plurality of second members formed in areas between adjacent first members. The first members and the second members are configured to reflect and guide at least a portion of light emitted from the light emitting sections through the first members.

### CROSS REFERENCES TO RELATED APPLICATIONS

The present application claims priority to Japanese Priority Patent Application JP 2012-033053 filed in the Japan Patent Office on Feb. 17, 2012, the entire content of which is hereby incorporated by reference.

### BACKGROUND

In general, the present disclosure relates to a display apparatus. More specifically, the present disclosure relates to a display apparatus employing light emitting devices and relates to a method for manufacturing the display apparatus.

In recent years, an illumination apparatus and an organic electro luminescence display apparatus have been becoming popular. The illumination apparatus and the organic electro luminescence display apparatus are apparatus employing organic electro luminescence devices as light emitting devices. In the following description, the organic electro luminescence device is referred to simply as an organic EL device whereas the organic electro luminescence display apparatus is referred to simply as an organic EL display apparatus. In addition, in the field of the organic EL display apparatus, there is a strong demand for development of a technology for fetching light with a high degree of efficiency. If the efficiency of fetching light is low, the amount of the light actually emitted from the organic EL device is not utilized effectively. Thus, the organic EL display apparatus incurs a big loss in the power consumption and the like.

In order to increase the light fetching efficiency, there has been provided an organic EL display apparatus having a reflector as disclosed in Japanese Patent Laid-open No. 2007-248484 (hereinafter referred to as Patent Document 1). The organic EL display apparatus disclosed in Patent Document 1 includes a light guiding section 50 facing each display device serving as a light emitting device 20 on a sealing substrate 30. The light guiding section 50 serves as a reflector. The light guiding section 50 has a light incidence surface 51 facing the light emitting devices 20 and a light exit surface 52 on a side opposite to the light incidence surface 51. In addition, the light guiding section 50 has typically a trapezoidal cross-sectional surface spread in a direction from the light incidence surface 51 to the light exit surface 52. On a side surface 53 of the light guiding section 50, a light reflecting film 54 is formed. The light reflecting film 54 is a multi-layer film made of a metallic simple substance, a metallic alloy or a derivative material. Typical examples of the metal are aluminum (Al) and silver (Ag). In addition, a space enclosed by the light reflecting films 54 of light guiding sections 50 adjacent to each other can be filled up with air or at least a portion of such a space can be filled up with an intermediate layer 40. The display device 20 is provided on a driving substrate 10 whereas the light guiding section 50 is provided on the sealing substrate 30. The driving substrate 10 is pasted on the sealing substrate 30 by making use of a bonding-agent layer 41 made of typically thermally hardened resin or ultraviolet-ray hardened resin. The driving substrate 10 is pasted on the sealing substrate 30 in such a way that the display device 20 is exposed to the light guiding section 50. In addition, it is possible to have complete light reflection on the side surface 53 by setting a difference in refractive index between the inside of the light guiding section 50 and the outside of the light guiding section 50. It is to be noted that, in the following description, the existing reflector structure described above is referred to as a facing reflector structure for the sake of convenience.

### SUMMARY

As described above, in the organic EL display apparatus disclosed in Patent Document 1, the display device 20 is covered by the bonding-agent layer 41. That is to say, the bonding-agent layer 41 exists in a space between the display device 20 and the light guiding section 50. Thus, light emitted by the display device 20 is completely reflected on a boundary face between the display device 20 and the bonding-agent layer 41. It is therefore feared that the light fetching efficiency may decrease in some cases. The light fetching efficiency is an efficiency at which the light emitted by the display device 20 is effectively used outside the display device 20. In addition, in some cases, light originating from the display device 20 and passing through the bonding-agent layer 41 does not propagate to the light reflecting film 54 of the light guiding section 50 for the display device 20. Instead, such light inadvertently enters a portion enclosed by the light reflecting film 54 of the adjacent light guiding section 50. On top of that, even though it is possible to set a difference in refractive index between the inside of the light guiding section 50 and the outside of the light guiding section 50 in order to provide complete light reflection on the side surface 53, Patent Document 1 does not include any concrete descriptions as to what value the difference in refractive index should be set at.

It is thus desirable to provide a display apparatus capable of further increasing the efficiency of fetching light emitted by the light emitting device to the outside and a method for manufacturing the apparatus. In addition, it is further desirable to provide a method for manufacturing a simple display apparatus capable of further increasing the efficiency of fetching light emitted by the light emitting device to the outside and a method for manufacturing the apparatus.

In order to achieve the first desire described above, in an embodiment, a display device is provided including a plurality of light emitting devices formed on a substrate, a plurality of first members corresponding to the light emitting devices and formed directly on a portion of the respective light emitting device, and a plurality of second members formed in areas between adjacent first members. The first members and the second members are configured to reflect and guide at least a portion of light emitted from the light emitting sections through the first members.

In another embodiment, an electronic apparatus is provided including a display device including a plurality of light emitting devices formed on a substrate, a plurality of first members corresponding to the light emitting devices and formed directly on a portion of the respective light emitting device, and a plurality of second members formed in areas between adjacent first members. In this embodiment, the first members and the second members are configured to reflect and guide at least a portion of light emitted from the light emitting sections through the first members.

In another embodiment, a method of manufacturing a display device is provided. The method includes forming a plurality of light emitting devices on a substrate, forming a plurality of first members corresponding to the light emitting devices directly on a portion of the respective light emitting device, and forming a plurality of second members formed in areas between adjacent first members. In this embodiment, the first members and the second members are configured to reflect and guide at least a portion of light emitted from the light emitting sections through the first members.

In another embodiment, a display device is provided including a plurality of light emitting devices formed on a substrate, a plurality of first members corresponding to the light emitting devices, each first member formed over a respective one of the light emitting devices, and a plurality of second members formed in areas between adjacent first members. In this embodiment, a value of a refractive index n1 of the first members is different than a value of a refractive index n₂ of the second members.

According to the embodiments, it is possible to further increase the efficiency of fetching light emitted by the light emitting device to the outside even without providing a light reflecting member and the like on the boundary face between the first and second members. In addition, in accordance with the method provided by the first method embodiment to serve as a method for manufacturing a display apparatus, the first member is created directly above the second electrode. Thus, unlike the existing technology, there is no loss of light fetched from light emitted by the light emitting device. Such a loss would otherwise be incurred due to existence of a bonding-agent layer at a location between the second electrode and the reflector. On top of that, in accordance with the method provided by the second method embodiment to serve as a method for manufacturing a display apparatus, by making use of a stamper, it is possible to obtain the light reflecting layer including the bonding-agent layer serving as the second member and the resin-material layer serving as the first member. Thus, by adoption of such a simple manufacturing method, it is possible to manufacture a display apparatus capable of increasing the efficiency of fetching light emitted by the light emitting device to the outside.

Additional features and advantages are described herein, and will be apparent from the following Detailed Description and the figures.

### BRIEF DESCRIPTION OF THE FIGURES

FIG. 1 is a model diagram showing a portion of a cross section of a display apparatus according to a first embodiment;

FIGS. 2A and 2B are each a model diagram showing a matrix of sub-pixels in a display apparatus according to the first to fifth embodiments;

FIG. 3 is a diagram showing graphs representing simulation results of radiation angle distributions of the luminance in the display apparatus according to the first embodiment and a typical comparison display apparatus 1′;

FIGS. 4A and 4B are diagrams showing simulation results of input/output states of light beams in a display apparatus according to a third embodiment and a typical comparison display apparatus 3;

FIG. 5A is a diagram showing simulation results of radiation angle distributions of the luminance in the display apparatus according to the third embodiment, the typical comparison display apparatus 3 and a typical comparison display apparatus 3′ whereas FIG. 5B is a diagram showing a graph representing an energy distribution in a first member of the display apparatus according to the third embodiment with the viewing-field angle of light from a light emitting device taken as a parameter;

FIG. 6 is a model diagram showing a portion of a cross section of a display apparatus according to a fourth embodiment;

FIG. 7 is a diagram showing simulation results of radiation angle distributions of the luminance in the display apparatus according to a fourth embodiment 4B;

FIG. 8 is a model diagram showing a portion of a cross section of a display apparatus according to a fifth embodiment;

FIGS. 9A to 9F are diagrams each showing a portion of a cross section of a first substrate and the like and each serving as an explanatory drawing to be referred to in description of an outline of a method for manufacturing the display apparatus according to the first embodiment, that is, a method provided by a first method embodiment of the present disclosure to serve as a method for manufacturing a display apparatus;

FIGS. 10A to 10D are diagrams each showing a portion of a cross section of a glass substrate and the like and each serving as an explanatory drawing to be referred to in description of an outline of another method for manufacturing the display apparatus according to the first embodiment, that is, a method provided by a second method embodiment of the present disclosure to serve as another method for manufacturing the display apparatus; and

FIG. 11 is a model diagram showing a portion of a cross section of a typical modified version obtained by modifying the display apparatus according to a fourth embodiment.

### DETAILED DESCRIPTION

Embodiments of the present application will be described below in detail with reference to the drawings.

Next, by referring to the diagrams, embodiments of the present disclosure are explained below. However, implementations of the present disclosure are by no means limited to the embodiments. That is to say, a variety of numbers used in the embodiments and a variety of materials used in the embodiments are no more than typical. It is to be noted that the explanation of the present disclosure is divided into topics arranged in the following order.

1: General description of a display apparatus according to the present disclosure and methods provided by first and second method embodiments of the present disclosure to serve as methods each adopted for manufacturing the display apparatus

2: First embodiment (a display apparatus according to the present disclosure and methods provided by first and second method embodiments of the present disclosure to serve as methods each adopted for manufacturing the display apparatus)

3: Second embodiment (a modified version of the first embodiment)

4: Third embodiment (another modified version of the first embodiment)

5: Fourth embodiment (a further modified version of the first embodiment)

6: Fifth embodiment (a still further modified version of the first embodiment) and others

General description of a display apparatus according to the present disclosure and methods provided by first and second method embodiments of the present disclosure to serve as methods each adopted for manufacturing the display apparatus

In the following description, a display apparatus according to the present disclosure and a display apparatus manufactured by adoption of a method provided by a first or second method embodiment of the present disclosure to serve as a method for manufacturing a display apparatus may be generically referred to simply as a display apparatus provided by the present disclosure in some cases.

It is desirable that, in the display apparatus provided by the present disclosure or a display apparatus manufactured by adoption of a method provided by a second method embodiment of the present disclosure to serve as a method for manufacturing a display apparatus, a light emitting device and a first member are adjacent to each other. Thus, light emitted by a light emitting section always directly propagates to the first member. As a result, the light fetching efficiency by no means decreases.

The display apparatus provided by the present disclosure to serve as a display apparatus including the desirable configuration described above can be set as an embodiment for outputting light emitted by each light emitting device to the outside by way of a second substrate. It is to be noted that such a display apparatus may be referred to as a display apparatus having a top light emission type in some cases. However, display apparatus according to the present disclosure are by no means limited to the display apparatus having a top light emission type. For example, it is also possible to adopt a structure in which light emitted by each light emitting device is output to the outside by way of a first substrate. It is to be noted that the display apparatus having a structure for outputting light emitted by each light emitting device to the outside by way of a first substrate may be referred to as a display apparatus having a bottom light emission type in some cases.

In the desirable embodiment implementing a display apparatus having a top light emission type, a protection film and a sealing material layer are further formed on the light reflecting layer. In this case, it is desirable to provide a configuration in which the following relation holds true:

|n₃−n₄|≦0.3

As an alternative, it is desirable to provide a configuration in which a relation given below desirably holds true:

|n₃−n₄|≦0.2

In the above relations, reference notations n₃ and n₄ denote the refraction indexes of the protection film and the sealing material layer respectively. It is thus possible to effectively prevent light from being reflected and scattered on the boundary face between the protection film and the sealing material layer. It is to be noted that a configuration can also be provided to serve as a configuration in which the first member and the protection film are created at the same time and combined with each other to form an integrated body. In addition, in the top light emission display apparatus including such a desirable configuration, the amount of light emitted by a light emitting device and output to the outside by way of the first member and a second substrate can be set at a value in a range of 1.5 to 2.0 where the value of 1 represents the amount of light emitted by the center of the light emitting device.

If the display apparatus is a color display apparatus, one pixel in the color display apparatus is configured to include three sub-pixels or at least four pixels. The three sub-pixels are a red-light emitting sub-pixel for emitting light having a red color, a green-light emitting sub-pixel for emitting light having a green color and a blue-light emitting sub-pixel for emitting light having a blue color. In such a color display apparatus, it is possible to provide a configuration described as follows. The red-light emitting sub-pixel is configured from a light emitting device for emitting light having a red color, the green-light emitting sub-pixel is configured from a light emitting device for emitting light having a green color whereas the blue-light emitting sub-pixel is configured from a light emitting device for emitting light having a blue color. In the top light emission display apparatus including such a desirable configuration, the second substrate can be configured to include a color filter whereas the light emitting device can be configured to emit light having a white color. In addition, each colored-light emitting sub-pixel can be configured from a combination of a light emitting device for emitting light having a white color and the color filter. In such a configuration, the second substrate can be configured to include a light blocking film referred to as a black matrix. By the same token, in the display apparatus of the bottom light emission type, the first substrate can be configured to include a color filter and a light blocking film referred to as a black matrix.

In the display apparatus having a desirable configuration according to an embodiment of the present disclosure as described above, a pixel or a sub-pixel can be configured from a light emitting device. In this case, the first member may be created to have the shape of a headless circular cone (or a headless rotary body) which satisfies the following relations:

0.5≦R₁/R₂≦0.8 and

0.5≦H/R₁≦2.0

In the above relations, reference notation R₁ denotes the diameter of the light incidence surface of the first member, reference notation R₂ denotes the diameter of the light exit surface of the first member whereas reference notation H denotes the height of the first member.

It is to be noted that the cross-sectional shape of the inclined surface of the headless circular cone can be a straight line, a combination of a plurality of segments or a curved line. It is also to be kept in mind that the cross-sectional shape of the headless circular cone is the shape of a cross section obtained by cutting the headless circular cone over a virtual plane including the axis line of the headless circular cone. This technical term “cross-sectional shape” is used with the same meaning in the following description.

In addition, it is desirable that the following relation is satisfied:

0.5≦R₀/R₁≦1.0

In the above relation, reference notation R₀ denotes the diameter of the light emitting section.

As an alternative, in the display apparatus having a desirable configuration according to an embodiment of the present disclosure as described above, a pixel or a sub-pixel can be configured to include a plurality of light emitting devices collected to form a set. In this case, the first member may be created to have the shape of a headless circular cone (or a headless rotary body) which satisfies the following relations:

0.5≦R₁/R₂≦0.8 and

0.5≦H/R₁≦2.0

In the above relations, reference notation R₁ denotes the diameter of the light incidence surface of the first member, reference notation R₂ denotes the diameter of the light exit surface of the first member whereas reference notation H denotes the height of the first member.

The number of light emitting devices collected to form a pixel or a sub-pixel can be set at a value in a typical range of 3 to 1,000. It is to be noted that the cross-sectional shape of the inclined surface of the headless circular cone can be a straight line, a combination of a plurality of segments or a curved line. In addition, it is desirable that the following relation is satisfied:

0.5≦R₀/R₁≦1.0

In the above relation, reference notation R₀ denotes the diameter of the light emitting section.

On top of that, in the display apparatus having a desirable configuration according to an embodiment of the present disclosure as described above, a material used for making the first member can be Si₁₋ₓNₓ, ITO (Indium-Tin Oxide), IZO (Indium-Zinc Oxide), TiO₂, Nb₂O₅, a polymer containing Br (bromine), a polymer containing S (sulfur), a polymer containing titan or a polymer containing zirconium, to mention a few. On the other hand, a material used for making the second member can be SiO₂, MgF, LiF, polyimide resin, acryl resin, fluorine resin, silicon resin, a fluorine-series polymer or a silicon-series polymer, to mention a few.

The display apparatus and the like which are provided by the present disclosure to include a desired implementation and a desired configuration which are explained above may also be referred to hereafter as a presently disclosed display apparatus used as a generic technical term for the display apparatus. The display apparatus may also include an implementation in which a second electrode is created between the first and second members or an organic layer and the second electrode are created between the first and second members. In such a case, on the boundary face between the second member and the second electrode or on the boundary face between the second member and the organic layer, at least a part of light propagating through the first member is reflected. These implementations are also included in the implementation wherein, on the surface of the second member facing the first member, at least a part of light propagating through the first member is reflected.

In the presently disclosed display apparatus, a pixel or a sub-pixel may be configured from one light emitting device. However, implementations of the present disclosure are by no means limited to an embodiment in which a pixel or a sub-pixel is configured from one light emitting device. In this case, pixels or sub-pixels may be laid out to form a stripe array, a diagonal array, a delta array or a rectangular array, to mention a few. In addition, implementations of the present disclosure are by no means limited to an embodiment in which a pixel or a sub-pixel is configured from a plurality of collected light emitting devices. In this case, pixels or sub-pixels may be laid out to form a stripe array.

In the following description, the first electrode in the display apparatus of the top light emission type and the second electrode in the display apparatus of the bottom light emission type are also referred to as a light reflecting electrode in some cases for the sake of convenience. The light reflecting electrode is made of a material capable of serving as a light reflecting material. With the light reflecting electrode functioning as the anode electrode, the light reflecting electrode is made of a metal or an alloy. The metal and the alloy have a high work-function value. Typical examples of such a metal are as Pt (platinum), Au (gold), Ag (silver), Cr (chrome), W (tungsten), Ni (nickel), Cu (copper), Fe (iron), Co (cobalt) and Ta (tantalum), to mention a few, whereas typical examples of the alloy are the Ag—Pd—Cu alloy and the Al—Pd alloy. The Ag—Pd—Cu alloy contains Ag (silver) as the main component, Pd (palladium) having a mass in a range of 0.3% to 1% and Cu (copper) having a mass in a range of 0.3% to 1%. In addition, the material can be Al (aluminum) or an alloy including Al (aluminum). In this case, if the value of the work function of Al (aluminum) or the value of the work function of the alloy including Al (aluminum) or the like is small and the material has a high light reflection ratio, the hole injection characteristic can be improved by typically providing a proper hole injection layer. By improving the hole injection characteristic, the light reflecting electrode can be used as an anode electrode. The light reflecting electrode can have a typical thickness in a range of 0.1 μm to 1 μm. As an alternative, it is also possible to adopt a structure in which transparent conductive materials each having an excellent hole injection characteristic are provided to form a stack on a dielectric multi-layer film or a light reflecting film having a good light reflection characteristic. A typical example of such a light reflecting film is Al (aluminum) whereas typical examples of such transparent conductive material are an ITO (Indium-Tin Oxide) and an IZO (Indium-Zinc Oxide). With the light reflecting electrode functioning as the cathode electrode, on the other hand, it is desirable that the light reflecting electrode is made of a conductive material having a small work-function value and a high light reflection ratio. If the electron injection characteristic is improved by typically providing a proper electron injection layer on the conductive material used for making the anode electrode as a material having a high light reflection ratio, however, the light reflecting electrode can also be used as the cathode electrode.

In the following description, the second electrode in the display apparatus of the top light emission type and the first electrode in the display apparatus of the bottom light emission type are also referred to as a light semi-transmissive electrode in some cases for the sake of convenience. A material used for making the light semi-transmissive electrode can be a light semi-transmissive material or a light transmissive material. With the light semi-transmissive electrode functioning as the cathode electrode, it is desirable that the material used for making the light semi-transmissive electrode is a conductive material which transmits emitted light and has a small work-function value so that electrons can be injected into an organic layer with a high degree of efficiency. Typical examples of such a material are a metal and an alloy which have a small work-function value. Typical examples of the metal having a small work-function value are Al (aluminum), Ag (silver), Mg (magnesium), Ca (calcium), Na (natrium) and Sr (strontium), to mention a few. On the other hand, typical examples of the alloy having a small work-function value are an alloy of an alkali metal or an alkali earth metal and Ag (silver), an alloy of Mg (magnesium), an alloy of Al (aluminum) and Li (lithium). A typical example of the alloy of an alkali metal or an alkali earth metal and Ag (silver) is an Mg—Ag alloy which is an alloy of Mg (magnesium) and Ag (silver) whereas a typical example of the alloy of Mg (magnesium) is an Mg—Ca alloy. On the other hand, the alloy of Al (aluminum) and Li (lithium) is referred to as an Al—Li alloy. Among the metals and the alloys, the Mg—Ag alloy is most desirable. In this alloy, the Mg:Ag ratio representing the ratio of the volume of the magnesium to the volume of the silver can be set at a typical value in a range of 5:1 to 30:1. In the case of the Mg—Ca alloy, on the other hand, the Mg:Ca ratio representing the ratio of the volume of the magnesium to the volume of the calcium can be set at a typical value in a range of 2:1 to 10:1. The thickness of the light semi-transmissive electrode can be set at a typical value in a range of 4 nm to 50 nm, a desirable value in a range of 4 nm to 20 nm or a more desirable value in a range of 6 nm to 12 nm. As an alternative, the light semi-transmissive electrode can also be designed into a laminated structure including the material layer explained before and the so-called transparent electrode which are arranged in an order starting from an organic-layer side. Made of typically an ITO or an IZO, the transparent electrode has a typical thickness in a range of 3×10⁻⁸ m to 1×10⁻⁶ m. If the light semi-transmissive electrode is designed into such a laminated structure, the thickness of the material layer explained before can be reduced to a value in a range of 1 nm to 4 nm. In addition, the light semi-transmissive electrode can also be configured only from the transparent electrode. As an alternative, a bus electrode serving as a supplementary electrode can be provided for the light semi-transmissive electrode. By making the bus electrode from a material having a small resistance, the resistance of the entire light semi-transmissive electrode can be reduced. Typical examples of the material having a small resistance are aluminum, an aluminum alloy, silver, a silver alloy, copper, a copper alloy, gold and a gold alloy, to mention a few. If the light semi-transmissive electrode functions as the anode electrode, on the other hand, it is desirable that the light semi-transmissive electrode is made of a material which transmits emitted light and has a large work-function value.

The method for creating the first and second electrodes can be typically an evaporation method such as an electronic-beam evaporation method, a heated-filament evaporation method or a vacuum evaporation method, a sputtering method, a CVD (Chemical Vacuum Deposition) method, an MOCVD method, a combination of an ion plating method and an etching method, any one of a plurality of printing methods such as a screen printing method, an ink jet printing method and a metal-mask printing method, a plating method such as an electrical plating method or an non-electrolytic plating method, a lift-off method, a laser abrasion method or a sol-gel method, to mention a few. By adopting one of the printing methods or one of the plating methods, it is possible to directly create the first and second electrodes each having a desired shape or a desired pattern. It is to be noted that, in order to create the first and second electrodes after creation of the organic layer, a film formation method is particularly recommended because the film formation method is capable of preventing the organic layer from being damaged. In this case, the film creation method can be the vacuum evaporation method with a small energy of the film formation particle or the MOCVD method. This is because, if the organic layer is damaged, it is feared that a no-light emitting pixel or a no-light emitting sub-pixel is created. The no-light emitting pixel and the no-light emitting sub-pixel do not emit light because a leak current flows due to the damaged organic layer. The no-light emitting pixel and the no-light emitting sub-pixel are each referred to as a vanishing point. In addition, the fact that a sequence of processes can be carried out without exposing the processes to the atmosphere is desirable because the organic layer can be prevented from being damaged by moistures in the atmosphere. In this case, the processes range from a process of creating the organic layers to a process of creating electrodes of the organic layers. In some cases, patterning can be eliminated from the process of creating one of the first and second electrodes.

In the display apparatus provided by the present disclosure, a plurality of light emitting devices are created on the first substrate. In this case, the first or second substrate can be a high distortion spot glass substrate, a soda glass (Na₂O.CaO.SiO₂) substrate, a borosilicate glass (Na₂O.B₂O₃.SiO₂) substrate, a forsterite (2MgO.SiO₂) substrate, a lead glass (Na₂O.PbO.SiO₂) substrate, a variety of glass substrates each having an insulation film formed on the surface thereof, a quartz substrate, a quartz substrate having an insulation film formed on the surface thereof, a silicon substrate having an insulation film formed on the surface thereof or an organic polymer substrate, to mention a few. Typical examples of the organic polymer substrate are a poly methyl methacrylate substrate also referred to as a PMMA (poly methyl methacrylate acid) substrate, a PVA (Poly Vinyl Alcohol) substrate, a PVP (Poly Vinyl Phenol) substrate, a PES (Poly Ether Sulfone) substrate, a polyimide substrate, a polycarbonate substrate and a PET (Poly Ethylene Terephthalate) substrate, to mention a few. The organic polymer is a form of the high molecular material used for making a plastic film, a plastic sheet or a plastic substrate which are configured from the high molecular material to exhibit a burnable characteristic. The material used for making the first substrate can be the same as or different from the material used for making the second substrate. In the case of the display apparatus having the bottom light emission type, however, the material used for making the first substrate is required to be transmissive for light emitted by the light emitting device.

The organic EL display apparatus also referred to as the organic electro luminescence display apparatus can be given as a typical example of the display apparatus provided by the present disclosure. If the organic EL display apparatus is a color organic EL display apparatus, as described before, each sub-pixel is configured from one of organic EL devices forming the organic EL apparatus. In this case, one pixel includes typically three different sub-pixels which are typically a red-light emitting sub-pixel for emitting light having a red color, a green-light emitting sub-pixel for emitting light having a green color and a blue-light emitting sub-pixel for emitting light having a blue color. Thus, if the number of organic EL devices forming the organic EL apparatus is N×M in such a configuration, the number of pixels is (N×M)/3. The organic EL display apparatus can be typically used as a display apparatus embedded in a personal computer, a TV receiver, a mobile phone, a PDA (Personal Digital Assistant), a game machine and the like. As an alternative, the organic EL display apparatus can be used in an EVF (Electronic View Finder) and an HMD (Head-Mounted Display). Another typical example of the display apparatus provided by the present disclosure is an illumination apparatus including a backlight for a liquid-crystal display apparatus and a planar light source for a liquid-crystal display apparatus.

The organic layer includes a light emitting layer typically made of an organic light emitting material. To put it concretely, the organic layer can be configured from typically a laminated structure including a hole transport layer, a light emitting layer and an electron transport layer, a laminated structure including a hole transport layer and a light emitting layer also serving as an electron transport layer and a laminated structure including a hole injection layer, a hole transport layer, a light emitting layer, an electron transport layer and an electron injection layer. Let each of these laminated structures be referred to as a tandem unit. In this case, the organic layer is said to have a two-stage tandem structure including a first tandem unit, a connection layer and a second tandem unit which form a stack. As a matter of fact, the organic layer can be configured into a multistage tandem structure constructed from three or more tandem units forming a stack. In these cases, the color of emitted light is changed to a red color, a green color or a blue color for the tandem units in order to provide an organic layer emitting a white color as a whole. Typical examples of the method for creating the organic layer are a PVD (Physical Vapor Deposition) method such as a vacuum evaporation method, a printing method such as a screen printing method or an ink jet printing method, a laser transfer method and a variety of coating methods. The laser transfer method is a method for transferring an organic layer. In accordance with the laser transfer method, a laser beam is radiated to a laminated structure including a laser absorption layer and an organic layer, which are created on a transfer substrate, in order to separate the organic layer from the laser absorption layer. If the organic layer is created by adoption of the vacuum evaporation method, for example, a material passing through a hole provided on the so-called metal mask used in the vacuum evaporation method is deposited in order to obtain the organic layer. As an alternative, the organic layer is created on the entire surface without carrying out a patterning process.

In the display apparatus of the top light emission type, the first electrode is provided typically on the inter-layer insulation layer. In addition, this inter-layer insulation layer covers the light emitting device driving section created on the first substrate. The light emitting device driving section is configured to include one TFT (Thin Film Transistor) or a plurality of TFTs. The TFT and the first electrode are electrically connected to each other through a contact plug provided on the inter-layer insulation layer. Typical examples of the material used for making the inter-layer insulation layer are SiO₂, BPSG, PSG, BSG, AsSg, PbSg, SiON, SOG (Spin On Glass), glass having a low melting point, an SiO₂ series material referred to as a glass paste, a SiN series material and a variety of insulation resin materials. The resin insulation materials include polyimide resin, novolac series resin, acryl series resin and polybenzoxazole resin. If the inter-layer insulation layer is made of insulation resin, a single insulation resin material can be used as it is or a plurality of insulation resin materials are properly combined to produce a material to be used for making the inter-layer insulation layer. The inter-layer insulation layer can be created by carrying out a commonly known process adopting typically a CVD method, a coating method, a sputtering method or any one of a variety of printing methods.

In a bottom light emission display apparatus having a configuration/structure in which light emitted by the light emitting device passes through the inter-layer insulation layer, it is necessary to make the inter-layer insulation layer from a material transmissive for light emitted by the light emitting device. In addition, it is also necessary to create a light emitting device driving section in such a way that the light emitting device driving section does not block light emitted by the light emitting device. In the display apparatus having the bottom light emission type, the light emitting device driving section can be provided over the second electrode.

As explained before, it is desirable that an insulative or conductive protection film is provided over the organic layer for the purpose of protecting the organic layer against moistures. It is also desirable that the protection film is formed by adoption a film creation method with a particularly small film formation particle energy as is the case with a vacuum evaporation method or adoption of a film creation method such as a CVD method or an MOCVD method. This is because, by forming the protection film in this way, the effect on the foundation layer can be reduced. As an alternative, it is desirable that, in order to prevent the luminance from decreasing due to deterioration of the organic layer, the film formation temperature is set at a normal temperature and, in order to prevent the protection film from being peeled off, the protection film is formed under a condition which minimizes the stress of the protection film. In addition, it is also desirable that the protection film is formed by not exposing the electrodes already created to the atmosphere. By forming the protection film in this way, it is possible to prevent the organic layer from deteriorating due to moistures of the atmosphere and/or the oxygen in the atmosphere. On top of that, it is also desirable that, in the case of a display apparatus having the top light emission type, the protection film is formed from a material transmitting light, which is generated by the organic layer, at a transmittance ratio of at least 80%. To put it concretely, it is desirable that the protection film is formed from an insulative material having an inorganic amorphous characteristic. Typical examples of such an insulative material are given below. Since the insulative material having an inorganic amorphous characteristic does not generate grains, the water permeability of the material is low and the material can be used for making a good protection film. To put it concretely, it is desirable that the material used for making the protection film is a material which is transmissive for light emitted by the light emitting layer but elaborately blocks moistures. To put it more concretely, typical examples of such an insulative material are amorphous silicon (α-Si), amorphous silicon carbide (α-SiC), amorphous silicon nitride (α-Si₁₋ₓNₓ), amorphous silicon oxide (α-Si_{1-y}O_{y}), amorphous carbon (α-C), amorphous silicon oxide-nitride (α-SiON) and AL₂O₃, to mention a few. It is to be noted that, if the material used for making the protection film is a conductive material, the protection film can be made of a transparent conductive material such as ITO and IZO.

In order to further increase the light fetching efficiency, the display apparatus provided by the present disclosure can be provided with a resonator structure. To put it concretely, let a first boundary face be a boundary face between the first electrode and the organic layer whereas a second boundary face be a boundary face between the second electrode and the organic layer. In this case, it is possible to provide a configuration in which light emitted by the light emitting layer is resonated between the first boundary face and the second boundary face, and part of the light is output from the second electrode. It is to be noted that, in the following description, such a display apparatus is referred to as an A display apparatus provided by the present disclosure for the sake of convenience. In addition, let reference notation L₁ denote the distance from the maximum light emission position on the light emitting layer to the first boundary face, reference notation OL₁ denote the optical distance, reference notation L₂ denote the distance from the maximum light emission position on the light emitting layer to the second boundary face, reference notation OL₂ denote the optical distance whereas reference notations m₁ and m₂ each denote an integer. In this case, relations (1-1), (1-2), (1-3) and (1-4) given below hold true.

0.7{−Φ₁/(2π)+m₁}≦2×OL₁/λ≦1.2{−Φ₁/(2π)+m₁} (1-1)

0.7{−Φ₂/(2π)+m₂}≦2×OL₂/λ≦1.2{−Φ₂/(2π)+m₂} (1-2)

L₁<L₂ (1-3)

m₁<m₂ (1-4)

In the above relations, the following reference notations are used:

λ, denotes the maximum peak wavelength of a spectrum of light emitted by the light emitting layer or denotes a desired wavelength in light emitted by the light emitting layer.

Φ₁ denotes the quantity of a reflected-light phase shift generated on the first boundary face. The quantity of the reflected-light phase shift is expressed in terms of radians and has a value in the following range −2π<Φ₁≦0.

Φ₂ denotes the quantity of a reflected-light phase shift generated on the second boundary face. The quantity of the reflected-light phase shift is expressed in terms of radians and has a value in the following range −2π<Φ₂≦0.

It is to be noted that the distance L₁ from the maximum light emission position on the light emitting layer to the first boundary face is an actual distance or a physical distance from the maximum light emission position on the light emitting layer to the first boundary face. By the same token, the distance L₂ from the maximum light emission position on the light emitting layer to the second boundary face is also an actual distance or a physical distance from the maximum light emission position on the light emitting layer to the second boundary face. On the other hand, also referred to as an optical path length, the optical distance OL is generally the length of an optical path travelled by a light beam propagating through a medium with a refractive index n for the physical distance L. Thus, the optical distance OL is equal to n×L (that is, OL=n×L). This equation holds true for the optical distance OL as follows:

OL₁=L₁×n₀

OL₂=L₁×n₀

In the above equations, reference notation n₀ denotes the average refractive index of the organic layer. The average refractive index is computed by finding the sum of the product of refractive indexes and thicknesses of layers composing the organic layer and then dividing the sum by the thickness of the organic layer.

In the A display apparatus provided by the present disclosure, it is desirable that the average light reflection ratio of the first electrode has a value not smaller than 50% or, desirably, a value not smaller than 80%. On the other hand, it is desirable that the average light reflection ratio of the second electrode has a value in a range of 50% to 90% or, desirably, a value in a range of 60% to 90%. It is to be noted that, by interpreting the technical term “first electrode” used in the above description as the second electrode and by interpreting the technical term “second electrode” used in the above description as the first electrode, the above description can be regarded as description of a B display apparatus provided by the present disclosure. The B display apparatus provided by the present disclosure will be explained separately later.

In addition, the A display apparatus provided by the present disclosure can have a configuration in which the first electrode is made of a light reflecting material, the second electrode is made of a semi-transmitting material and the constants m₁ and m₂ are set at respectively 0 and 1 (that is, m₁=0 and m₂=1) which provide the highest light fetching efficiency. As is obvious from the above description, the display apparatus provided by the present disclosure includes the A display apparatus provided by the present disclosure. It is desirable that, in the display apparatus provided by the present disclosure, the thickness of the hole transport layer or the hole supplying layer is about equal to the thickness of the electron transport layer or the electron supplying layer. As an alternative, the electron transport layer or the electron supplying layer is made thicker than the hole transport layer or the hole supplying layer respectively so that, with a low driving voltage, it is possible to provide the light emitting layer with electrons necessary and sufficient for increasing the efficiency. That is to say, by providing the hole transport layer at a location between the first electrode serving as the anode electrode and the light emitting layer and by setting the thickness of the hole transport layer at a value smaller than the thickness of the electron transport layer, the number of supplied holes can be increased. In addition, in such a configuration, it is possible to obtain carrier balance assuring a sufficiently large supply of carriers without supplying holes and electrons in excess or deficiency. Thus, a high light emission efficiency can be obtained. On top of that, since supplied holes and supplied electrons are not in excess or deficiency, it is possible to make the carrier balance hardly collapsible, suppress driving deteriorations and lengthen the light emission life.

As described above, in order to further increase the light fetching efficiency, the display apparatus provided by the present disclosure can be provided with a resonator structure. To put it concretely, let a first boundary face be a boundary face between the first electrode and the organic layer whereas a second boundary face be a boundary face between the second electrode and the organic layer. In this case, it is possible to provide a configuration in which light emitted by the light emitting layer is resonated between the first boundary face and the second boundary face, and part of the light is output from the first electrode. It is to be noted that, in the following description, such a display apparatus is referred to as a B display apparatus provided by the present disclosure for the sake of convenience. In addition, let reference notation L₁ denote the distance from the maximum light emission position on the light emitting layer to the first boundary face, reference notation OL₁ denote the optical distance, reference notation denote the distance from the maximum light emission position on the light emitting layer to the second boundary face, reference notation OL₂ denote the optical distance whereas reference notations m₁ and m₂ each denote an integer. In this case, relations (2-1), (2-2), (2-3) and (2-4) given below hold true.

0.7{−Φ₁/(2π)+m₁}≦2×OL₁/λ≦1.2{−Φ₁/(2π)+m₁} (2-1)

0.7{−Φ₂/(2π)+m₂}≦2×OL₂/λ≦1.2{−Φ₂/(2π)+m₂} (2-2)

L₁>L₂ (2-3)

m₁>m₂ (2-4)

In the above relations, the following reference notations are used:

λ denotes the maximum peak wavelength of a spectrum of light emitted by the light emitting layer or denotes a desired wavelength in light emitted by the light emitting layer.

Φ₁ denotes the quantity of a reflected-light phase shift generated on the first boundary face. The quantity of the reflected-light phase shift is expressed in terms of radians and has a value in the following range −2π<Φ₁≦0.

Φ₂ denotes the quantity of a reflected-light phase shift generated on the second boundary face. The quantity of the reflected-light phase shift is expressed in terms of radians and has a value in the following range −2π<Φ₂≦0.

In addition, the B display apparatus provided by the present disclosure can have a configuration in which the first electrode is made of a semi-light transmitting material, the second electrode is made of a light reflecting material and the constants m₁ and m₂ are set at respectively 1 and 0 (that is, m₁=1 and m₂=0) which provide the highest light fetching efficiency. As is obvious from the above description, the display apparatus provided by the present disclosure includes the B display apparatus provided by the present disclosure. It is desirable that, in the display apparatus provided by the present disclosure, the thickness of the hole transport layer or the hole supplying layer is about equal to the thickness of the electron transport layer or the electron supplying layer. As an alternative, the electron transport layer or the electron supplying layer is made thicker than the hole transport layer or the hole supplying layer so that, with a low driving voltage, it is possible to provide the light emitting layer with electrons necessary and sufficient for increasing the efficiency. That is to say, by providing the hole transport layer at a location between the second electrode serving as the anode electrode and the light emitting layer and by setting the thickness of the hole transport layer at a value smaller than the thickness of the electron transport layer, the number of supplied holes can be increased. In addition, in such a configuration, it is possible to obtain carrier balance assuring a sufficiently large supply of carriers without supplying holes and electrons in excess or deficiency. Thus, a high light emission efficiency can be obtained. On top of that, since supplied holes and supplied electrons are not excess or deficiency, it is possible to make the carrier balance hardly collapsible, suppress driving deteriorations and lengthen the light emission life.

The first and second electrodes absorb part of incident light and reflect the remaining light. Thus, a phase shift is generated in the reflected light. The phase-shift quantities Φ₁ and Φ₂ can be found by computation based on measured values of the real and imaginary parts of the complex refractive indexes of materials which the first and second electrodes are made of. The values of the real and imaginary parts are measured typically by making use of an ellipsometer. For more information, refer to a reference such as “Principles of Optic,” Max Born and Emil Wolf, 1974 (Pergamon Press). It is to be noted that the refractive indexes of the organic layer and others can also be measured by making use of an ellipsometer.

In the display apparatus provided by the present disclosure which can be the A display apparatus provided by the present disclosure or the B display apparatus provided by the present disclosure, the first member is configured from a portion of a rotary body. A typical example of the portion of a rotary body is a headless rotary body. In this case, the rotation axis of the rotary body serves as the axis of the first member. Let reference notation z denote the rotation axis of the rotary body or the axis of the first member and let a cross-sectional shape of the first member be obtained by cutting the first member over a virtual plane including the z axis. In this case, the cross-sectional shape of the first member is a trapezoidal shape or the shape of a portion of a parabolic line. As an alternative, the cross-sectional shape of the first member can also be a shape other than the trapezoidal shape or the shape of a portion of a parabolic line. Typical examples of the surface of the rotary body are the surface of a sphere, the surface of a rotary ellipse, the surface of a rotary parabola and a curved surface obtained by rotating a portion of a curved line. Typical examples of the curved line are a polynomial line of at least the third order, a two-leaf line, a three-leaf line, a four-leaf line, a lemniscafe line, a cochlear line, a correct-leaf line, a conchoidal line, a cissoid line, a likelihood line, an tractrix line, a dangling line, a cycloid line, a trochoid line, an astroid line, a third order semi parabolic line, a Lissajous curved line, a witch of agnesi, an external cycloid line, a heart-shaped line, an internal cycloid line, a clothoid curved line and a spiral line, to mention a few. In addition, in some cases, it is also possible to make use of a surface obtained by combining a plurality of line segments or combining a plurality of line segments and a plurality of curved lines and then rotating the combination.

### First Embodiment

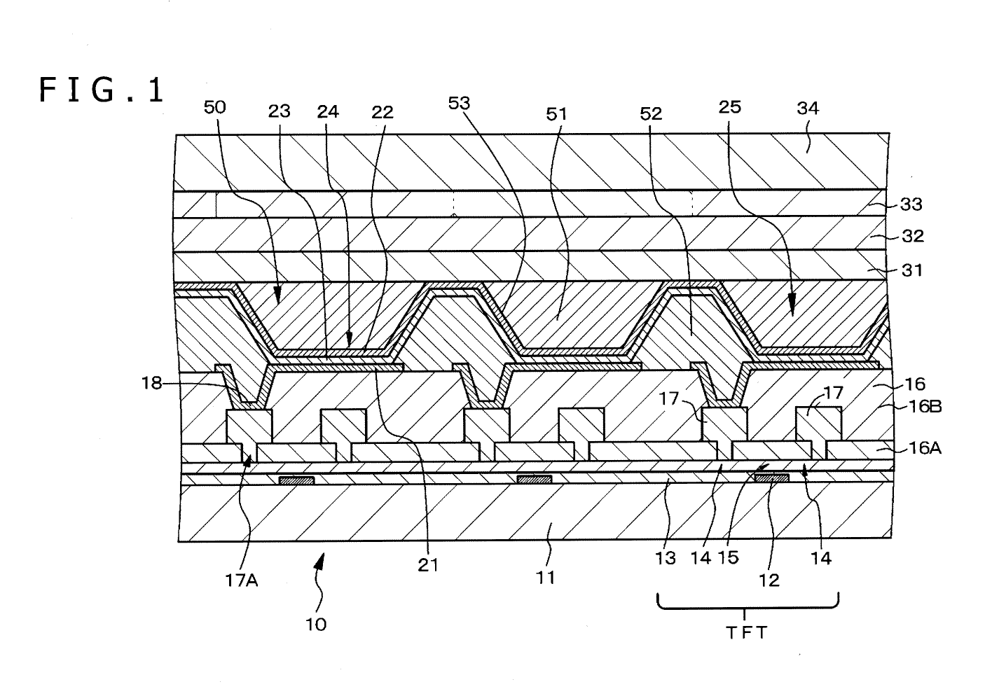

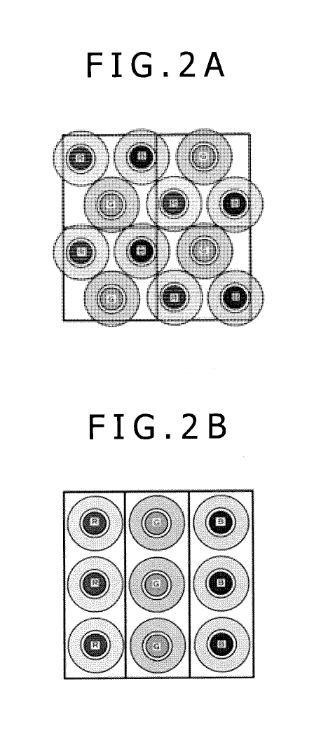

A first embodiment implements a display apparatus provided by the present disclosure or, to be more specific, an organic EL display apparatus. In addition, the first embodiment also implements first and second method embodiments provided by the present disclosure to serve as first and second method embodiments of a method for manufacturing the display apparatus according to the first embodiment. FIG. 1 is a model diagram showing a portion of a cross section of the display apparatus according to the first embodiment whereas FIG. 2A is a model diagram showing a matrix of sub-pixels in the display apparatus. In the following description, the display apparatus according to the first embodiment is also referred to simply as an organic EL display apparatus in some cases. The organic EL display apparatus according to the first embodiment is an active-matrix organic EL display apparatus for displaying color images. The organic EL display apparatus according to the first embodiment is a display apparatus having the top light emission type. That is to say, light is output through the second electrode.

As shown in FIG. 1, the organic EL display apparatus according to the first embodiment or second to fifth embodiments to be described later includes:

(A) a first substrate 11 on which a plurality of light emitting devices 10 each having a laminated stack including a first electrode 21, a light emitting section 24 configured to have an organic layer 23 typically including a light emitting layer made of an organic light emitting material and a second electrode 22 are created; and

(B) a second substrate 34 provided over the second electrode 22.

In the following description, the light emitting device 10 is also referred to as an organic EL device. The light emitting device 10 employed in the organic EL display apparatus according to the first embodiment or the second to fourth embodiments to be described later includes:

(a) the first electrode 21;

(b) a second member 52 having an aperture 25 whose bottom is exposed to the first electrode 21;

(c) the organic layer 23 which is placed at least over a portion of the first electrode 21 exposed to the bottom of the aperture 25 and is typically provided with a light emitting layer made of an organic light emitting material; and

(d) the second electrode 22 created on the organic layer 23.

In addition, the first substrate 11 employed in the organic EL display apparatus according to the first embodiment or the second to fifth embodiments to be described later has a light reflecting layer 50 including:

a first member 51 for propagating light emitted by the light emitting device 10 and outputting the light to the outside; and

a second member 52 filling up a space between the adjacent first members 51.

The organic EL display apparatus according to the first embodiment or the second, fourth and fifth embodiments to be described later is a high definition display apparatus applicable to an EVF (Electronic View Finder) or an HMD (Head-Mounted Display). On the other hand, the organic EL display apparatus according to the third embodiment is a large-size organic EL display apparatus having a size larger than the organic EL display apparatus according to the first embodiment or the second, fourth and fifth embodiments. Typically, the organic EL display apparatus according to the third embodiment is applied to a television receiver.

In addition, one pixel is configured to include three sub-pixels. The three sub-pixels are a red-light emitting sub-pixel for emitting light having a red color, a green-light emitting sub-pixel for emitting light having a green color and a blue-light emitting sub-pixel for emitting light having a blue color. On top of that, the second substrate 34 is provided with a color filter 33 whereas the light emitting device 10 emits light having a white color. In this case, a colored-light emitting sub-pixel is configured from a combination of a light emitting device 10 emitting light having a white color and a color filter 33. The color filter 33 is configured from an area transmitting light having a red color, an area transmitting light having a green color or an area transmitting light having a blue color. However, the configuration of the color filter 33 is by no means limited to such a structure. For example, it is possible to adopt a two-stage tandem structure including two tandem units forming a stack. In this case, the entire organic layer 23 has a structure emitting light having a white color. A tandem unit is typically configured from a laminated structure including a hole transport layer and a light emitting layer also functioning as an electron transport layer. In addition, it is also possible to provide a light blocking film referred to as a black matrix between adjacent color filters 33. If the number of pixels is 2,048×1,236 and one light emitting device 10 forms one sub-pixel, the number of light emitting devices 10 is three times the number of pixels. In the organic EL display apparatus according to the first embodiment or the second, fourth and fifth embodiments to be described later, as shown in FIG. 2A, the array of sub-pixels is a pseudo delta array in which the size of a pixel enclosed by a solid line is 5 μm×5 μm. It is to be noted that FIG. 2A shows four pixels. In FIGS. 2A and 2B, reference notations R, G and B denote a red-light emitting sub-pixel, a green-light emitting sub-pixel and a blue-light emitting sub-pixel respectively. In this configuration, the light emitting device 10 and the first member 51 are brought into contact with each other. To put it concretely, the second electrode 22 and the first member 51 are brought into direct contact with each other.

In addition, the first member 51 is created to have the shape of a headless circular cone (or a headless rotary body) which satisfies the following relations:

0.5≦R₁/R₂≦0.8 and

0.5≦H/R₁≦2.0

In the above relations, reference notation R₁ denotes the diameter of the light incidence surface of the first member 51, reference notation R₂ denotes the diameter of the light exit surface of the first member 51 whereas reference notation H denotes the height of the first member 51. In the first embodiment, the light incidence surface of the first member 51 is a face exposed to the first substrate 11 whereas the light exit surface of the first member 51 is a face exposed to the second substrate 34. The values of these notations are shown in Table 1 hereunder.

It is to be noted that the cross-sectional shape of the inclined surface of the first member 51 which is a headless circular cone is a straight line. In addition, the cross-sectional shape of the headless circular cone is the shape of a cross section obtained by cutting the headless circular cone over a virtual plane including the axis line of the headless circular cone. The cross-sectional shape of the headless circular cone (that is, the cross-sectional shape of the first member 51) is trapezoidal.

In the organic EL display apparatus according to the first embodiment or the second, third and fourth embodiments to be described later, the first electrode 21 is used as an anode electrode whereas the second electrode 22 is used as a cathode electrode. The first electrode 21 is made of a light reflecting material. To put it concretely, the first electrode 21 is made of an Al—Nd alloy. On the other hand, the second electrode 22 is made of a light semi-transmitting material. To put it concretely, the second electrode 22 is made of a conductive material including Mg (magnesium). To put it more concretely, the second electrode 22 is made of an Mg—Ag alloy having a thickness of 10 nm. The first electrode 21 is created by adopting a combination of a vacuum evaporation method and an etching method. On the other hand, the second electrode 22 is created by adoption of a film formation method having a particularly small energy of the film formation particle. A typical example of the film formation method having a particularly small energy of the film formation particle is the vacuum evaporation method. The second electrode 22 is created without carrying out a patterning process. Results of measuring the refractive indexes of the first electrode 21 and the second electrode 22 are shown in table 2. The measurements were carried out for a wavelength of 530 nm. On the other hand, results of measuring the light reflection ratios of the first electrode 21 and the second electrode 22 are given as follows.

The light reflection ratio of the first electrode 21 is 85%.

The light reflection ratio of the second electrode 22 is 57%.

In the organic EL display apparatus according to the first embodiment or the second to fifth embodiments to be described later, the first electrode 21 of the organic EL device is provided on an inter-layer insulation layer 16 made of SiON and created by adoption of a CVD method. To put it concretely, the first electrode 21 is provided on an upper-level inter-layer insulation layer 16B. The inter-layer insulation layer 16 covers an organic EL device driving section created on the first substrate 11. The organic EL device driving section is configured to employ a plurality of TFTs. The TFTs are each electrically connected to the first electrode 21 through a contact plug 18 provided on the inter-layer insulation layer 16 or, strictly speaking, the upper-level inter-layer insulation layer 16B, a wire 17 and a contact plug 17A. It is to be noted that FIG. 1 shows one TFT for every organic EL device driving section. The TFT includes a gate electrode 12, a gate insulation film 13, source and drain areas 14 and a channel creation area 15. The gate electrode 12 is created on the first substrate 11. The gate insulation film 13 is created on the first substrate 11 and the gate electrode 12. The source and drain areas 14 are provided on a semiconductor layer created on the gate insulation film 13. The channel creation area 15 is created between the source and drain areas 14. The channel creation area 15 corresponds to a semiconductor-layer portion positioned over the gate electrode 12. In the typical configuration shown in the figure, the TFT is created as a transistor of the bottom gate type. It is to be noted, however, that, the TFT can also be created as a transistor of the top gate type. The gate electrode 12 of the TFT is connected to a scanning circuit not shown in the figure.

In the organic EL display apparatus according to the first embodiment or the second, fourth and fifth embodiments to be described later, the first substrate 11 is configured from a silicon substrate whereas the second substrate is made of non-alkali glass or quartz glass. In the case of the third embodiment to be described later and embodiments 4A to 4D also to be described later, on the other hand, both the first substrate 11 and the second substrate are made of non-alkali glass or quartz glass.

In addition, in the organic EL display apparatus according to the first embodiment or the second to fifth embodiments to be described later, the first member 51 is made of Si₁₋ₓNₓ whereas the second member 52 is made of SiO₂. The refractive index n₁ of the first member 51 and the refractive index n₂ of the second member 52 satisfy the following relations.

1.1≦n₁≦1.8

(n₁−n₂)≧0.20

In addition, on the surface of the second member 52 facing the first member 51, that is, on the boundary face between the first member 51 and the second member 52, at least a part of light propagating through the first member 51 is reflected. To put it more concretely, since the organic layer 23 and the second electrode 22 are created between the first member 51 and the second member 52, at least a part of light propagating through the first member 51 is reflected on the boundary face between the second member 52 and the organic layer 23. In this case, the surface of the second member 52 facing the first member 51 corresponds to a light reflecting section (reflector) 53. It is to be noted that, for the sake of convenience, such a structure is referred to as an anode reflector structure in the following description.

On top of that, in the organic EL display apparatus according to the first embodiment or the second to fourth embodiments to be described later, a protection film 31 and a sealing-material layer 32 are further provided on the light reflecting layer 50. The protection film 31 is made of Si_{1-y}N_{y} whereas the sealing-material layer 32 is made of epoxy resin. The refractive index n₃ of the protection film 31 and the refractive index n₄ of the sealing-material layer 32 satisfy the following relation:

|n₃−n₄|≦0.3

and shown in Table 2 hereunder.

The protection film 31 is created by adoption of a plasma CVD method for the purpose of preventing moistures from arriving at the organic layer 23. It is to be noted that the first member 51 and the protection film 31 can also be created at the same time so that the first member 51 and the protection film 31 can be integrated into the structure of a single body. In addition, in the configuration shown in FIG. 1, the top surface of the first member 51 is set at the same level as the top surface of the second electrode 22 on the second member 52. However, the first member 51 may cover the second electrode 22 on the second member 52. That is to say, the first member 51 may cover the entire surface.

TABLE 1

| | | Embodiments | | | Typical comparison | |
|---|---|---|---|---|---|---|
| | | 1 | 2 | 3 | 3 | 3′ |
| R₁ | μm | 2.3 | 2.3 | 5.5 | 5.5 | Not |
| | | | | | | created |
| R₂ | μm | 3.8 | 3.8 | 9.4 | 9.4 | |
| R₁/R₂ | | 0.61 | 0.61 | 0.59 | 0.59 | |
| H | μm | 1.5 | 1.5 | 5.0 | 5.0 | |
| Angle (θ) | Degrees | 63 | 63 | 64 | 64 | |
| Aperture ratio | | — | 0.385 | — | — | — |
| Diameter R₀ | μm | — | 2.0 | 5.5 | 5.5 | 5.5 |
| of light | | | | | | |
| emitting section | | | | | | |
| Creation pitch | μm | — | 4.24 | 10 | 10 | 10 |
| of light | | | | | | |
| emitting section | | | | | | |
| Thickness of | μm | 3.0 | 3.0 | 3.0 | Not | Not |
| protection film | | | | | created | created |
| Thickness of | μm | — | 2.0 | 10.0 | | |
| sealing- | | | | | | |
| material layer | | | | | | |
| Thickness of | μm | Not | | | 3.5 | 3.5 |
| bonding layer | | created | | | | |
| Thickness of | μm | — | 2.0 | 2.0 | 2.0 | 2.0 |
| color filter | | | | | | |

TABLE 2

| | | | Imaginary |
|---|---|---|---|
| | | Real part | part |
| Refraction index of first electrode 21 | | 0.755 | 5.466 |
| Refraction index of second electrode 22 | | 0.617 | 3.904 |
| Refraction index of organic layer 23 | n₀ | 1.85 | 0 |
| Refraction index of first member 51 made | n₁ | 1.81 | 0 |
| of Si_{1-y}N_{y} | | | |
| Refraction index of second member 52 made | n₂ | 1.46 | 0 |
| of SiO₂ | | | |
| Refraction index of protection film 31 made | n₃ | 1.81 | 0 |
| of Si_{1-y}N_{y} | | | |
| Refraction index of sealing-material layer 32 | n₄ | 1.65 | 0 |

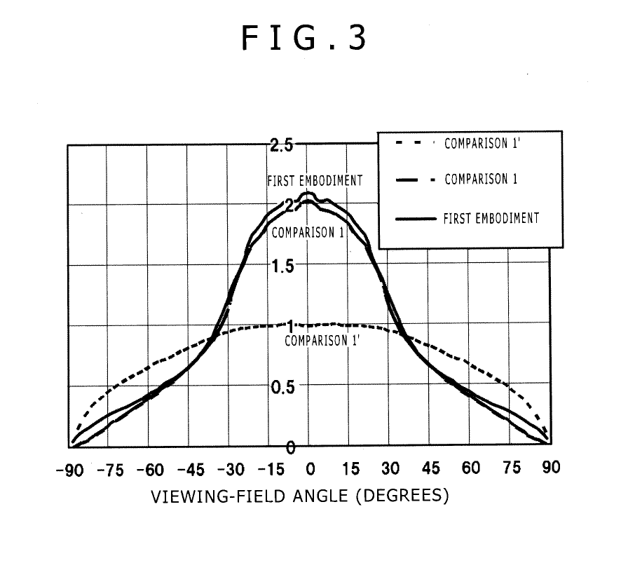

FIG. 3 is a diagram showing graphs representing simulation results of radiation angle distributions of the luminance in a typical comparison display apparatus 1, the display apparatus according to the first embodiment and a typical comparison display apparatus 1′. The typical comparison display apparatus 1 is the display apparatus in which an Al film serving as a light reflecting layer is created on the surface of the second member facing the first member, that is, on the boundary face between the first member and the second member. The display apparatus according to the first embodiment is an organic EL display apparatus having a configuration and a structure which are devised for the first embodiment. In this display apparatus according to the first embodiment, the equation (n₁−n₂)=0.20 holds true. The typical comparison display apparatus 1′ is an organic EL display apparatus having the same configuration and the same structure as the organic EL display apparatus according to the first embodiment except that an SiO₂ layer is created in place of the light reflecting layer 50.

It is to be noted that the horizontal axis of FIG. 3 represents the viewing-field angle expressed in terms of degrees whereas the vertical axis represents the luminance relative value which is a value normalized by setting the luminance at a viewing-field angle of 0 degrees at 1 for the typical comparison display apparatus 1′. FIG. 3 does not show differences of the radiation angle distributions of the luminance between the organic EL display apparatus according to the first embodiment and the organic EL display apparatus serving as the typical comparison display apparatus 1. As described above, the display apparatus according to the first embodiment has a configuration and a structure, which are devised for the first embodiment, and satisfies the equation (n₁−n₂)=0.20. In the typical comparison display apparatus 1, on the other hand, an Al film serving as a light reflecting layer is created on the surface of the second member facing the first member. In other words, if the equation (n₁−n₂)≧0.20 is satisfied, it is possible to obtain the same luminance increasing effect as the typical comparison display apparatus 1 in which an Al film serving as a light reflecting layer is created on the surface of the second member facing the first member.

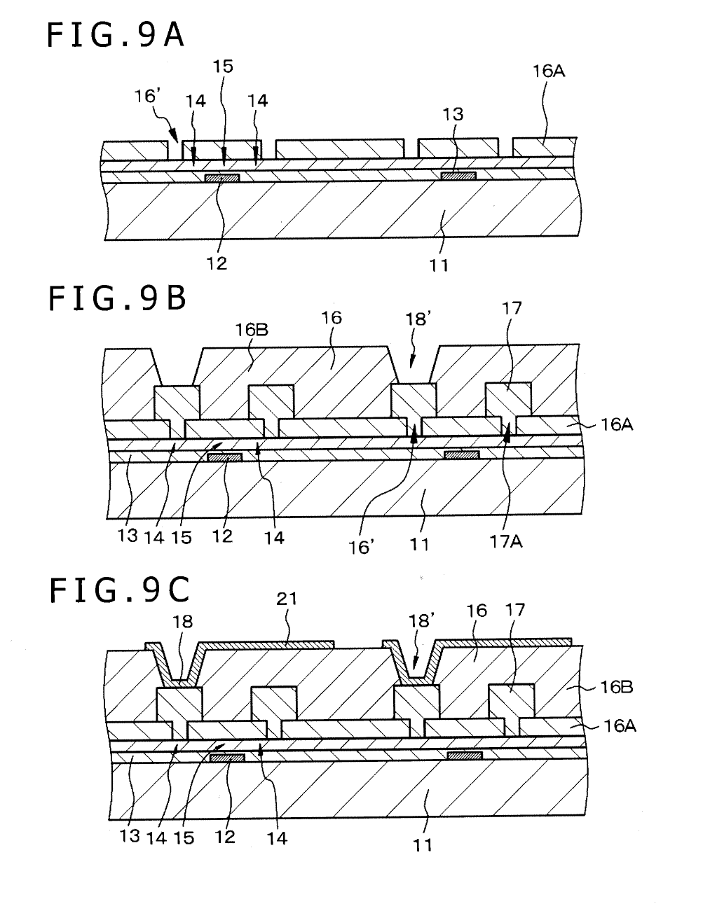

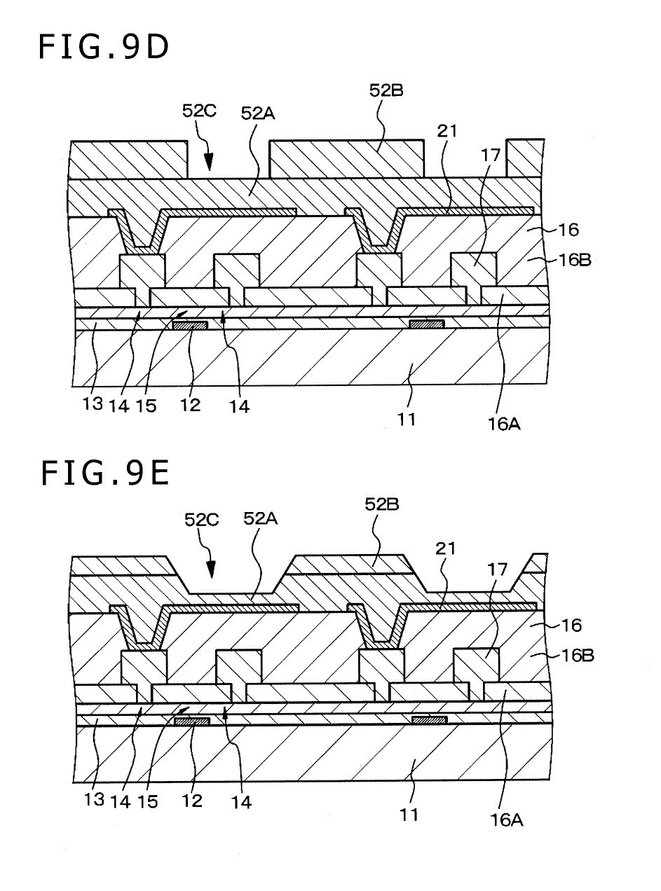

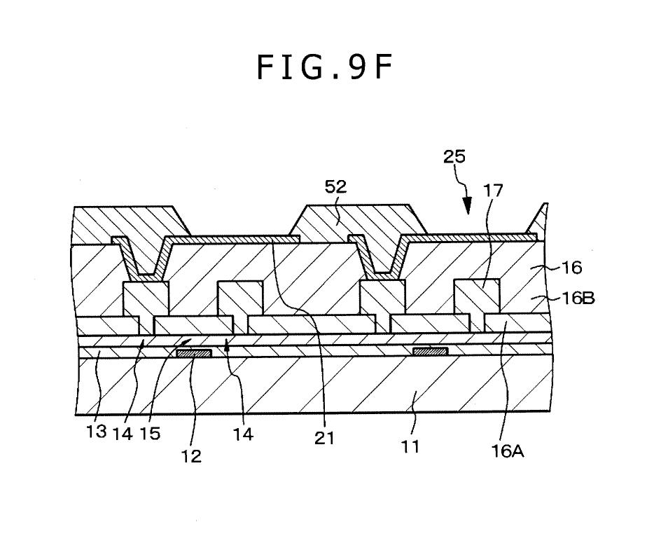

Next, by referring to FIGS. 9A to 9F, the following description explains an outline of a manufacturing method according to a first method embodiment of the present disclosure. The manufacturing method according to a first method embodiment is a method for manufacturing the organic EL display apparatus according to the first embodiment.

Process 100

First of all, a TFT is created on the first substrate 11 for every sub-pixel by adoption of a commonly known method. The TFT includes a gate electrode 12, a gate insulation film 13, source and drain areas 14 and a channel creation area 15. The gate electrode 12 is created on the first substrate 11. The gate insulation film 13 is created on the first substrate 11 and the gate electrode 12. The source and drain areas 14 are provided on a semiconductor layer created on the gate insulation film 13. The channel creation area 15 is created between the source and drain areas 14. The channel creation area 15 corresponds to a semiconductor-layer portion positioned over the gate electrode 12. In the typical configuration shown in the figure, the TFT is created as a transistor of the bottom gate type. It is to be noted, however, that, the TFT can also be created as a transistor of the top gate type. The gate electrode 12 of the TFT is connected to a scanning circuit not shown in the figure. Then, on the first substrate 11, a lower-level inter-layer insulation layer 16A made of SiO₂ is created to cover the TFT by adoption of the CVD method. After the lower-level inter-layer insulation layer 16A has been created, an aperture 16′ is created on the lower-level inter-layer insulation layer 16A on the basis of a photolithography technology and an etching technology. For more information on this process, refer to FIG. 9A.

Process 110

Then, a wire 17 made of aluminum is created on the lower-level inter-layer insulation layer 16A by adopting a combination of a vacuum evaporation method and an etching method. It is to be noted that the wire 17 is electrically connected the source and drain areas 14 of the TFT through a contact plug 17A provided inside the aperture 16′. The wire 17 is also electrically connected to a signal supplying circuit not shown in the figure. Then, the upper-level inter-layer insulation layer 16B made of SiO₂ is created on the entire surface by adoption of the CVD method. Subsequently, an aperture 18′ is created on an upper-level inter-layer insulation layer 16B on the basis of a photolithography technology and an etching technology. For more information on this process, refer to FIG. 9B.

Process 120

Later on, the first electrode 21 made of an Al—Nd alloy is created on the upper-level inter-layer insulation layer 16B by adopting a combination of a vacuum evaporation method and an etching method. For more information on this process, refer to FIG. 9C. It is to be noted that the first electrode 21 is electrically connected to the wire 17 through a contact plug 18 provided inside the aperture 18′.

Process 130

Then, the second member 52 is created. To put it concretely, a second-member configuration layer 52A made of SiO₂ is created on the entire surface by adoption of the CVD method and, then, a resist-material layer 52B is created on the second-member configuration layer 52A. Subsequently, the resist-material layer 52B is subjected to exposure and development processes in order to create an aperture 52C on the resist-material layer 52B. For clarification, refer to FIG. 9D. Then, the resist-material layer 52B and the second-member configuration layer 52A are etched by adoption of an RIE method in order to give a taper shape to the second-member configuration layer 52A as shown in FIG. 9E. Finally, it is possible to obtain the second member 52 sharing an inclined side wall with the aperture 25 as shown in FIG. 9F. It is to be noted that, by controlling the etching condition, the taper shape can be given to the second-member configuration layer 52A. However, the method for creating the second member 52 is by no means limited to such a method. For example, the second member 52 shown in FIG. 9F can also be created on the basis of a photolithography technology and a wet etching technology after a second-member configuration layer made of SiO₂ or polyimide resin has been created on the entire surface.

Process 140

Then, the organic layer 23 is created on the second member 52 including a part on a portion of the first electrode 21 exposed to the bottom of the aperture 25. That is to say, the organic layer 23 is created on the entire surface. It is to be noted that the organic layer 23 is a laminated stack constructed by sequentially creating typically a hole transport layer and a light emitting layer also serving as an electron transport layer formed of organic materials. The organic layer 23 can be obtained by carrying out a vacuum deposition process on an organic material on the basis of resistance heating.

Process 150

Later on, the second electrode 22 is created on the entire surface of the display area. The second electrode 22 covers the entire surface of the organic layer 23 forming N×M organic EL pixels. The second electrode 22 is insulated from the first electrode 21 by the second member 52 and the organic layer 23. The second electrode 22 is created by adoption of a vacuum evaporation method which is a film formation method whose energy of the film formation particle is so small that there is no effect on the organic layer 23. In addition, the second electrode 22 is created right after the creation of the organic layer 23 in the same vacuum evaporation apparatus as the organic layer 23 without exposing the organic layer 23 to the atmosphere. Thus, it is possible to prevent the organic layer 23 from deteriorating due to moistures and oxygen which are contained in the atmosphere. To put it concretely, by making a co-evaporated film from an Mg—Ag alloy having a volume ratio of 10:1 and forming the co-evaporated film having a thickness of 10 nm, the second electrode 22 can be obtained.

Process 160

Then, the first member 51 made of Si₁₋ₓNₓ (silicon nitride) is created on the entire surface prior to a flattening process. To put it concretely, the first member 51 is created on the second electrode 22. Thus, it is possible to obtain the light reflecting layer 50 from the first member 51 and the second member 52. In this way, an anode reflector structure can be obtained.

Process 170

Later on, an insulative protection film 31 made of Si_{1-y}N_{y} (silicon nitride) is created on the light reflecting layer 50 by adoption of the vacuum evaporation method. It is to be noted that the first member 51 and the protection film 31 can also be created at the same time so that the first member 51 and the protection film 31 can be integrated into the structure of a single body. In such a structure, due to an effect of the aperture 25, a dent may be created on the top surface of the protection film 31 in some cases. As described earlier, however, by prescribing the difference |n₃−n₄|, it is possible to effectively prevent light output by the light emitting device 10 from being scattered in the dent.

Process 180

Then, by making use of the sealing-material layer 32, the second substrate 34 having the color filter 33 created therein is bonded to the first substrate 11 having the protection film 31 created therein. Finally, by setting connections to external circuits, the manufacturing of the organic EL display apparatus can be completed.

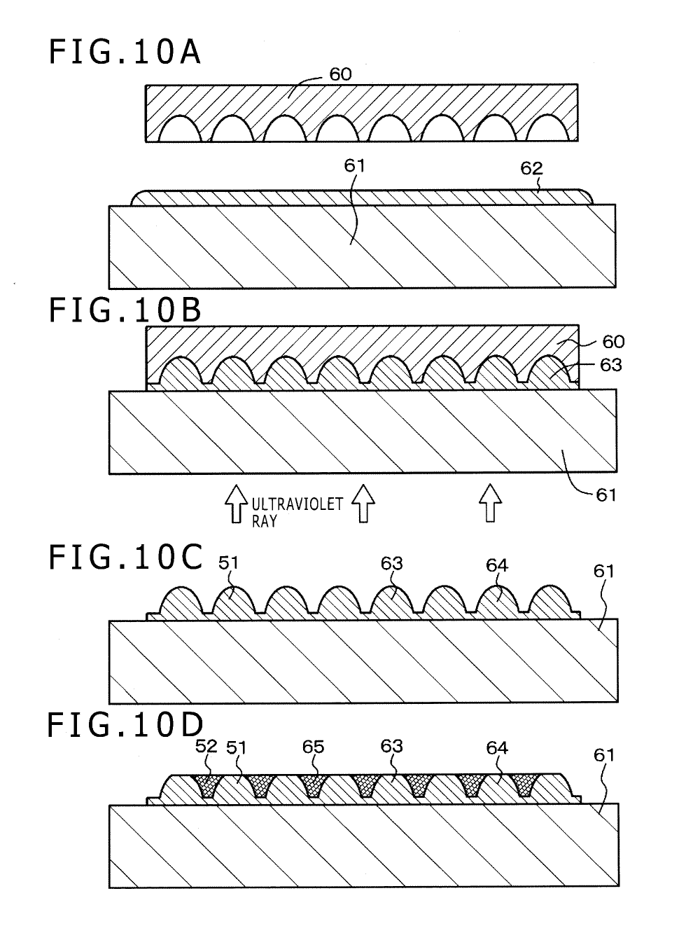

As an alternative, a light reflecting layer can also be created by adoption of a manufacturing method according to a second method embodiment of the present disclosure. The manufacturing method according to a second method embodiment is a method for manufacturing an organic EL display apparatus. Next, by referring to FIGS. 10A to 10D, the following description explains the second method embodiment provided by the present disclosure to serve as a method for manufacturing an organic EL display apparatus or, to put it more concretely, a method for manufacturing the light reflecting layer 50.

Process 100A

First of all, a stamper 60 having a shape complementary to the first member 51 is prepared. To put it concretely, the stamper (female) 60 having a shape complementary to the first member 51 is created by adoption of a commonly known technology. The commonly known technology is typically the electrocasting technology, the etching technology or another cutting technology.

Process 110A

In the mean time, a support substrate is coated with a resin material. To put it concretely, as shown in FIG. 10A, for example, an ultraviolet-ray hardened resin material 62 is applied to a light transmitting glass substrate 61 serving as the support substrate. That is to say, the resin material 62 is created on the glass substrate 61.

Process 120A

Then, after the resin material 62 has been formed by making use of the stamper 60, the stamper 60 is removed to obtain a resin-material layer 63 having protrusions 64. To put it concretely, with the stamper 60 put in a state of being pressed on the resin material 62, an energy beam or, more concretely, an ultraviolet ray is radiated from the side of the glass substrate 61 serving as the support substrate to the resin material 62 in order to harden the resin material 62 and to obtain the resin-material layer 63. After the resin-material layer 63 has been obtained as shown in FIG. 10B, the stamper 60 is removed. In this way, it is possible to obtain a resin-material layer 63 having protrusions 64 as shown in FIG. 10C. The protrusions 64 of the resin-material layer 63 each correspond to the first member 51.

Process 130A

Later on, the tips of the protrusions 64 of the resin-material layer 63 are flattened. Then, spaces between the protrusions 64 of the resin-material layer 63 are filled up with a bonding-agent layer 65 as shown in FIG. 10D.

Process 140A

Subsequently, the resin-material layer 63 is peeled off from the glass substrate 61 serving as the support substrate and mounted on the first substrate 11 in which light emitting devices and the like have been created. That is to say, the bonding-agent layer 65 is provided on the second electrode 22 so that the bonding-agent layer 65 does not obstruct light output from the light emitting device 10. In this way, the bonding-agent layer 65 is capable of serving as a bonding agent.

It is to be noted that the first substrate 11 can be obtained by carrying out processes in the same way as the processes 140 and 150 of creating the organic layer 23 and the second electrode 22 on the first electrode 21 and the upper-level inter-layer insulation layer 16B after the processes 100 to 120. In this way, it is possible to obtain the light reflecting layer 50 including the bonding-agent layer 65 serving as the second member 52 and the resin-material layer 63 serving as the first member 51. That is to say, the anode-reflector structure can be obtained.

Process 150A

Later on, the insulative protection film 31 is created on the light reflecting layer 50 by adoption of the plasma CVD method. Then, by making use of the sealing-material layer 32, the second substrate 34 in which the color filter 33 has been created is bonded to the first substrate 11 in which the protection film 31 has been created. Finally, by setting connections to external circuits, the manufacturing of the organic EL display apparatus can be completed. It is to be noted that, in place of the ultraviolet-ray hardened resin material 62, a thermally hardened resin material or a thermoplastic resin material can also be used.

In the case of the organic EL display apparatus according to the first embodiment, the value of the refractive index n1 of the first member 51 and the difference between the values of the refractive index n1 of the first member 51 and the refractive index n2 of the second member 52 are prescribed in advance. Thus, it is possible to reliably reflect at least part of light propagating through the first member 51 on the surface of the second member 52 facing the first member 51, that is, on the boundary face between the first member 51 and the second member 52 even without providing a light reflecting member or the like. In addition, it is also possible to reliably prevent light emitted by the light emitting device 10 from being completely reflected by the first member 51. That is to say, since the light emitting device 10 and the first member 51 are brought into contact with each other or, to put it concretely, since the second electrode 22 and the first member 51 are brought into direct contact with each other, it is possible to reliably prevent light emitted by the light emitting device 10 from being completely reflected by the first member 51. Thus, the light emitted by the light emitting device 10 can be output to the outside without loss. In addition, it is possible to attain all objectives including reduction of a driving current density to a value not greater than ½ times that of the existing organic EL display apparatus, enhancement of a luminance efficiency to a value not smaller than two times that of the existing organic EL display apparatus and reduction of a mixed-color ratio to a value not larger than 3%.

The organic EL display apparatus obtained as described above is the display apparatus according to the first embodiment or a display apparatus including:

(A) a first substrate 11 on which a plurality of light emitting devices 10 each having a laminated stack including a first electrode 21, a light emitting section 24 configured to have an organic layer 23 typically including a light emitting layer made of an organic light emitting material and a second electrode 22 are created; and

(B) a second substrate 34 provided over the second electrode 22, wherein

the first substrate 11 has a light reflecting layer 50 including

a first member 51 provided on the light emitting device 10 and used for propagating light emitted by the light emitting device 10 and outputting the light to the outside, and

a second member 52 filling up a space between the adjacent first members 51, and

at least part of light propagating through the first member 51 is reflected on the surface of the second member 52 facing the first member 51, that is, on the boundary face between the first member 51 and the second member 52.

### Second Embodiment

A second embodiment is a modified version of the first embodiment. Table 1 shows the structural data of the organic EL display apparatus according to the second embodiment and the organic EL display apparatus having a configuration and a structure which are devised for the first embodiment. The structural data includes the diameter R₁ of the light incidence surface of the first member 51, the diameter R₂ of the light exit surface of the first member 51, the height H of the first member 51, the gradient angle θ of the inclined surface of the headless circular cone shape of the first member 51, the thickness of the protection film 31, the thickness of the sealing-material layer 32, the thickness of the color filter 33, the diameter R₀ of the light emitting section 24 (or, to put it concretely, the diameter of the first electrode 21), the light emitting section creation pitch which is the distance from the center of any specific light emitting section 24 to the center of a light emitting section 24 adjacent to the specific light emitting section 24 and the aperture ratio, to mention a few.

As explained earlier, the organic EL display apparatus according to the second embodiment is a high definition display apparatus desirably applicable to an EVF (Electronic View Finder) or an HMD (Head-Mounted Display). In addition, except for the fact that a layer made of SiO₂ is provided in place of the light reflecting layer 50, a typical comparison display apparatus 2 is an organic EL display apparatus having a configuration and a structure which are identical with those of the organic EL display apparatus according to the second embodiment.

In addition, simulations have been carried out to obtain radiation-angle distributions of the luminance for the organic EL display apparatus according to the second embodiment and the typical comparison display apparatus 2. The results of the simulations indicate that, in a range of radiation angles of ±10 degrees, the luminance efficiency of the organic EL display apparatus according to the second embodiment is 2.55 times the luminance efficiency of the typical comparison display apparatus 2 whereas the driving current density of the organic EL display apparatus according to the second embodiment is 0.355 times the driving current density of the typical comparison display apparatus 2. In addition, if it is assumed that the color filter is shifted in the horizontal direction by 0.3 μm, the luminance efficiency of the organic EL display apparatus according to the second embodiment is 2.49 times the luminance efficiency of the typical comparison display apparatus 2, the driving current density of the organic EL display apparatus according to the second embodiment is 0.363 times the driving current density of the typical comparison display apparatus 2 whereas the mixed-color ratio of the organic EL display apparatus according to the second embodiment is 1.18%. The organic EL display apparatus according to the second embodiment is capable of attaining all objectives including reduction of a driving current density to a value not greater than ½ times that of the existing organic EL display apparatus, enhancement of a luminance efficiency to a value not smaller than two times that of the existing organic EL display apparatus and reduction of a mixed-color ratio to a value not larger than 3%. It is to be noted that, if the quantity of light emitted by the center of the light emitting device 10 in the organic EL display apparatus according to the second embodiment is assumed to be 1, the quantity of light output to the outside from the light emitting device 10 by way of the first member 51 and the second substrate 34 is 1.6.

### Third Embodiment

A third embodiment is also a modified version of the first embodiment. The organic EL display apparatus according to the third embodiment is used in a TV receiver. The size of each sub-pixel in the third embodiment is larger than that of a sub-pixel in the first embodiment. Thus, if a sub-pixel is configured from a light emitting device 10, the thickness of the light reflecting layer 50 naturally increases. For this reason, the sub-pixel of the third embodiment is configured from a set of a plurality of light emitting devices 10. To put it concretely, the sub-pixel of the third embodiment is configured from a set of 64 light emitting devices 10. It is to be noted that the size of a light emitting device 10 is 10 μm×10 μm and the following relations are satisfied:

0.5≦R₁/R₂≦0.8 and

0.5≦H/R₁≦2.0

The cross-sectional shape of the inclined surface of the headless circular cone is a straight line. In addition, the array of sub-pixels is a stripe array shown in FIG. 2B. It is to be noted that, in the stripe array shown in FIG. 2B, in order to make the figure simple, one sub-pixel is configured from a set of three light emitting devices 10.

Except for what has been described above, the organic EL display apparatus according to the third embodiment can be constructed to have a configuration and a structure which are similar to respectively the configuration and the structure which are devised for the organic EL display apparatus according to the first embodiment. Thus, detailed explanation of the configuration and the structure which are devised for the organic EL display apparatus according to the third embodiment is omitted. It is to be noted that, for example, after the second-member configuration layer made of polyimide resin has been created on the entire surface, the second member 52 shown in FIG. 9F can be created on the basis of a photolithography technology and an etching technology.

In the case of the third embodiment, as explained earlier, the first substrate 11 and the second substrate 34 are each configured from a glass substrate. In addition, the organic layer 23 is formed of a red-light emitting sub-pixel, a green-light emitting sub-pixel and a blue-light emitting sub-pixel. The red-light emitting sub-pixel is configured to include a red-light emitting device for emitting light having a red color whereas the green-light emitting sub-pixel is configured to include a green light emitting device for emitting light having a green color. On the other hand, the blue-light emitting sub-pixel is configured to include a blue-light emitting device for emitting light having a blue color. It is to be noted the light emitting device is configured to have a laminated structure including typically a hole transport layer and a light emitting layer also serving as an electron transport layer so as to provide a structure for emitting light having a white color. In addition, if such a laminated structure is referred to as a tandem unit, the organic layer 23 can be configured to have a two-stage tandem structure including two tandem units. If the organic layer 23 is created by adoption of the vacuum evaporation method, for example, a material passing through a hole provided on the so-called metal mask used in the vacuum evaporation method is deposited in order to obtain the organic layer 23 for each of the red-light emitting device, the green-light emitting device and the blue-light emitting device.

As described above, table 1 shows structural data of the organic EL display apparatus provided in accordance with the third embodiment as an organic EL display apparatus having a configuration and a structure which are basically identical with those of the first embodiment. The structural data includes the diameter R₁ of the light incidence surface of the first member 51, the diameter R₂ of the light exit surface of the first member 51, the height H of the first member 51, the gradient angle θ of the inclined surface of the headless circular cone shape of the first member 51, the thickness of the protection film 31, the thickness of the sealing-material layer 32, the thickness of the color filter 33 and the diameter R₀ of the light emitting section 24 (or, to put it concretely, the diameter of the first electrode 21), to mention a few. Also in the case of the organic EL display apparatus according to the third embodiment, the second electrode 22 and the first member 51 are brought into direct contact with each other.

In addition, in the organic EL display apparatus serving as a typical comparison display apparatus 3, the light emitting section 24 having the diameter R₀ shown in table 1 is created whereas the color filter 33 and a reflector are created on the second substrate 34. On top of that, the reflector of the second substrate 34 is bounded to the light emitting section 24 of the first substrate 11 through a bonding layer. That is to say, in this respect, the organic EL display apparatus serving as the typical comparison display apparatus 3 is the existing organic EL display apparatus having the facing reflector structure described earlier. The thickness of the bonding layer is set at 3.5 μm. In addition, the organic EL display apparatus serving as a typical comparison display apparatus 3′ has a structure constructed by eliminating the reflector from the organic EL display apparatus serving as the typical comparison display apparatus 3.

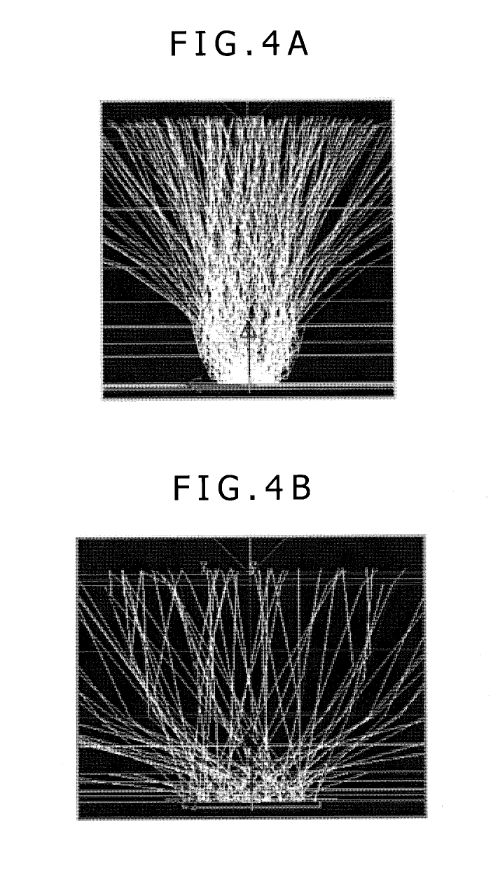

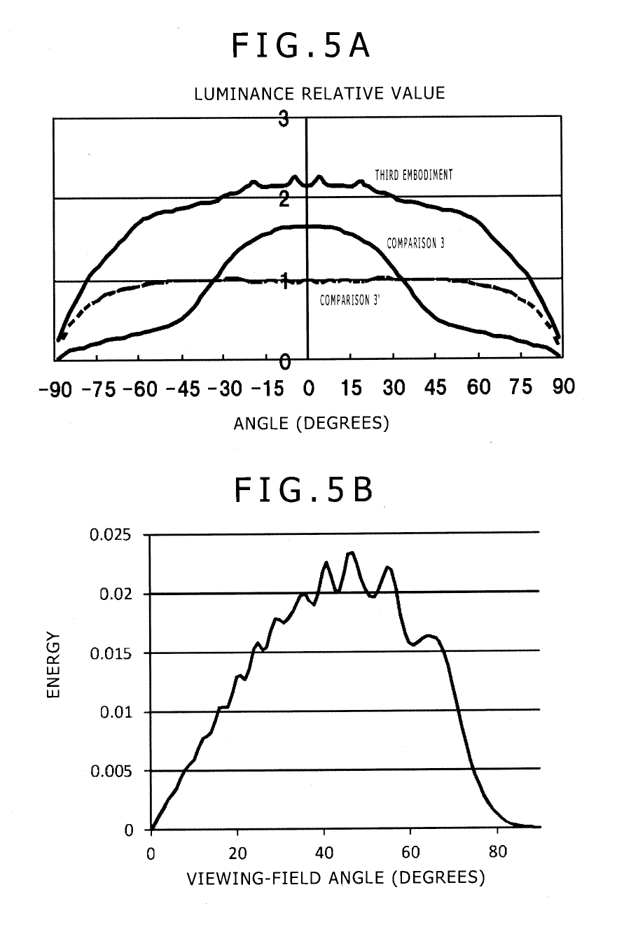

Furthermore, simulations have been carried out on the organic EL display apparatus according to the third embodiment, the organic EL display apparatus serving as the typical comparison display apparatus 3 and the organic EL display apparatus serving as the typical comparison display apparatus 3′ in order to find the front luminance, the light fetching efficiency and the luminance ratios to the front-luminance value at viewing-field angles of 45 degrees and 60 degrees. Results of the simulations are shown in table 3 below. In addition, simulations have been carried out on the organic EL display apparatus according to the third embodiment and the organic EL display apparatus serving as the typical comparison display apparatus 3 to find input/output states of light beams. Results of the simulations are shown in FIGS. 4A and 4B. On top of that, simulations have been carried out on the organic EL display apparatus according to the third embodiment, the organic EL display apparatus serving as the typical comparison display apparatus 3 and the organic EL display apparatus serving as the typical comparison display apparatus 3′ to find a radiation-angle distribution of the luminance. Results of the simulations are shown in FIGS. 5A and 5B. It is to be noted that the horizontal axis of FIG. 5A represents the viewing-field angle expressed in terms of degrees whereas the vertical axis represents the luminance relative value which is a value normalized by setting the luminance at a viewing-field angle of 0 degrees at 1 for the organic EL display apparatus serving as the typical comparison display apparatus 3′. Then, by setting the luminance at every viewing-field angle at 1.0 for the typical comparison display apparatus 3′, the luminance was found for each the organic EL display apparatus according to the third embodiment and the organic EL display apparatus serving as the typical comparison display apparatus 3. It is to be noted that, in table 3, viewing-field angles A and B are viewing-field angles of 45 and 60 degrees respectively. In addition, in table 3, values shown on columns of the viewing-field angles A and B are each the ratio of a luminance at the viewing-field angle to the front luminance.

TABLE 3

| | | | Viewing- | Viewing- |
|---|---|---|---|---|
| | Front | Light fetching | field | field |
| | luminance | efficiency | angle A | angle B |
| Third embodiment | 2.2 times | 1.9 times | 87% | 79% |
| Comparison 3 | 1.6 times | 1.4 times | 31% | 20% |
| Comparison 3′ | 1.0 times | 1.0 times | | |

As is obvious from FIG. 5A and table 3, the organic EL display apparatus according to the third embodiment has a characteristic very excellent in comparison with the organic EL display apparatus serving as the typical comparison display apparatus 3. This is because, in the case of the organic EL display apparatus according to the third embodiment, the second electrode 22 and the first member 51 are brought into direct contact with each other so that there is no fetching loss of light emitted by the light emitting device 10. In addition, as is obvious from FIG. 5A, in comparison with the organic EL display apparatus serving as the typical comparison display apparatus 3 and the organic EL display apparatus serving as the typical comparison display apparatus 3′, the organic EL display apparatus according to the third embodiment has not only a high front luminance value, but also high luminance relative values at large viewing-field angles. That is to say, the organic EL display apparatus according to the third embodiment has higher luminance values without regard to the viewing-field angle at which the user is looking at the organic EL display apparatus. Thus, the organic EL display apparatus according to the third embodiment is an organic EL display apparatus desirable for television receivers.

In addition, simulations have been carried out on the organic EL display apparatus according to the third embodiment to find a viewing-field angle distribution of an energy in the first member 51 by taking the viewing-field angle of light emitted by the light emitting device 10 as a variable parameter expressed in terms of degrees. A result of the simulations is shown in FIG. 5B. In this case, a critical angle is 33 degrees obtained by computing the value of the expression arcsin (1.0/1.81). The critical angle is a limit angle beyond which light cannot be output from the first member 51 having a refractive index of 1.81 to the atmosphere in a configuration including no reflector. Thus, light in a range of 0 degrees to 33 degrees shown in FIG. 5B can be output from the first member 51 to the atmosphere. This light represents 31% of all light output to the inside of the first member 51.

In the organic EL display apparatus serving as the typical comparison display apparatus 3, the reflector of the second substrate is bounded to the light emitting device of the first substrate through a bonding layer. Thus, light enters the reflector by way of the bonding layer. The critical angle for light incident to the bonding agent such as an acrylic series agent having a refractive index of about 1.5 is 56 degrees obtained by computing the value of the expression arcsin (1.5/1.81). Thus, it is possible to make use of light in a range not wider than a range of 0 degrees to 56 degrees shown in FIG. 5B. This light represents 75% of all light output to the inside of the first member.

In the case of the organic EL display apparatus according to the third embodiment in which the second electrode 22 and the first member 51 are brought into direct contact with each other, on the other hand, it is possible to make use of light in a range not wider than a range of 0 degrees to 90 degrees shown in FIG. 5B. This light represents 100% of all light output to the inside of the first member 51. Thus, in the case of the organic EL display apparatus according to the third embodiment, it is possible to make use of light having an amount up to 3 (=100/33) times the amount of light for a case in which no reflector is provided. In addition, in the case of the organic EL display apparatus according to the third embodiment, it is possible to make use of light having an amount up to 1.3 (=100/75) times the amount of light for the organic EL display apparatus serving as the typical comparison display apparatus 3. It is to be noted that the efficiency of fetching light propagating from the light emitting device 10 to the first member 51 is computed and multiplied by the intensity of emitted light inside the first member 51 in order to find the intensity of light inside the first member 51. After the intensity of light inside the first member 51 has been found, the intensity is integrated over all wavelengths in order to find an energy at a particular viewing-field angle. As is obvious from FIG. 5B, the light emitted by the light emitting device 10 has a large energy even at a large viewing-field angle. In other words, in the case of the organic EL display apparatus according to the third embodiment, the user can observe a bright image even at a large viewing-field angle.

### Fourth Embodiment

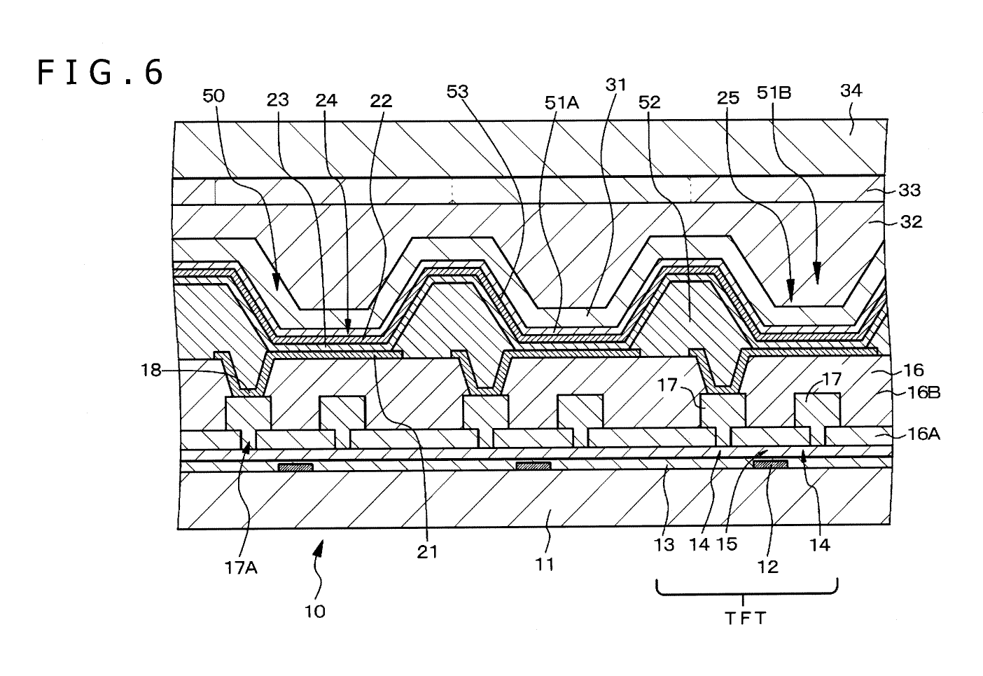

A fourth embodiment is also a modified version of the first embodiment. In the case of the first embodiment, the top surface of the first member 51 is positioned at about the same level as the top surface of the second member 52. That is to say, a space between adjacent second members 52 is filled up with a first member 51. In the case of the fourth embodiment, on the other hand, as is obvious from FIG. 6 which is a model diagram showing a portion of a cross section of a display apparatus according to the fourth embodiment, a first member 51A having a layer shape is created in an area between adjacent second members 52. To put it concretely, on the second electrode 22, the layer-shaped first member 51A having a refraction index n1 of 1.806 and an average thickness of 0.2 μm is created. An area 51B is an area over the first electrode 21. The area 51B is surrounded by the second members 52 and the layer-shaped first members 51A each created on one of the second members 52. Then, the insulative protection film 31 made of Si_{1-y}N_{y} (silicon nitride) is formed on the entire surface which is the area 51B and an area over the top surface of the second member 52. On top of that, the sealing-material layer 32 and the color filter 33 are created on the protection film 31. It is to be noted that a portion of the sealing-material layer 32 is extended to a region inside the area 518.

Except for what is described above, the organic EL display apparatus according to the fourth embodiment has a configuration identical with that of the organic EL display apparatus according to the first embodiment. Thus, the configuration of the organic EL display apparatus according to the fourth embodiment is not explained in detail.

In the case of the fourth embodiment 4A, the difference (|n₁−n₃|) between the refractive index n₁ of the first member 51A having a layer shape and the refractive index n₃ of the protection film 31 is set at a constant value of 0.2, that is, (|n₁−n₃|)=0.2. Simulations have been carried out on the fourth embodiment 4A by changing the refractive index n1 of the first member 51A in order to find light-quantity ratios. Results of the simulations are shown in table 4 given below. The light-quantity ratios shown in table 4 have been obtained by setting the light quantity of the typical comparison display apparatus 3′ at 1.00. That is to say, the light-quantity ratio for a case in the table 4 is a ratio of the light quantity for the case to the light quantity of the typical comparison display apparatus 3′. In addition, the refractive index n2 of the second member 52 has been set at 1.61. It is to be noted that parameters of the light reflecting layer employed in the organic EL display apparatus according to the fourth embodiment 4A are the same as the parameters shown in table 1 for the light reflecting layer employed in the organic EL display apparatus according to the third embodiment. In addition, the array of sub-pixels employed in the organic EL display apparatus according to the fourth embodiment 4A is the same as the array of sub-pixels employed in the organic EL display apparatus according to the third embodiment.

TABLE 4

| | Refractive index n₁ of | | |
|---|---|---|---|
| | layer-shaped first | Refractive index n₃ | Light-quantity |
| Case | member 51A | of protection film 31 | ratio |
| (11) | 1.9 | 1.7 | 1.32 |
| (12) | 1.8 | 1.6 | 1.33 |
| (13) | 1.7 | 1.5 | 1.37 |
| (14) | 1.6 | 1.4 | 1.27 |
| (15) | 1.8 | 2.0 | 1.45 |
| (16) | 1.7 | 1.9 | 1.47 |
| (17) | 1.6 | 1.8 | 1.51 |
| (18) | 1.5 | 1.7 | 1.56 |
| (19) | 1.4 | 1.6 | 1.60 |
| (20) | 1.3 | 1.5 | 1.64 |

As is obvious from table 4, if the difference (|n₁−n₃|) between the refractive index n₁ of the first member 51A having a layer shape and the refractive index n₃ of the protection film 31 is set at a constant value of 0.2, the first member 51A having a layer shape is capable of sufficiently displaying the function of a light reflection section serving as a reflector. In addition, if the refractive index n₁ of the first member 51A having a layer shape is larger than the refractive index n₃ of the protection film 31, the light-quantity ratio is relatively small as evidenced by numbers shown for cases (11) to (14) of table 4.

In addition, relations between the viewing-field angle and the luminance relative value have also been examined. As explained earlier, the luminance relative value is a normalized value obtained by setting the luminance at a viewing-field angle of 0 in the typical comparison display apparatus 3′ at 1. Results of the examination indicate that, for cases (11) and (12), in a range of a viewing-field angle of −90 degrees to a viewing-field angle of −40 degrees, the luminance relative value is relatively large whereas, in a range of a viewing-field angle of −40 degrees to a viewing-field angle of 0 degrees, the luminance relative value is relatively small. On the other hand, in a range of a viewing-field angle of 0 degrees to a viewing-field angle of 40 degrees, the luminance relative value is again relatively large whereas, in a range of a viewing-field angle of 40 degrees to a viewing-field angle of 90 degrees, the luminance relative value is again relatively small. That is to say, the results of the examination indicate that the luminance relative value has two peaks. It is thus obvious that, when the user is looking at the organic EL display apparatus from the front side, the luminance decreases.

From the results of the simulations, it is possible to draw a conclusion that it is desirable to set the difference (n₃−n₁) obtained by subtracting the refractive index n₁ of the first member 51A having a layer shape from the refractive index n₃ of the protection film 31 at a value not smaller than 0.2.

In addition, in the case of the fourth embodiment 4B, the refractive index n₃ of the protection film 31 is set at a constant value of 1.8 whereas the refractive index n₄ of the sealing-material layer 32 extended to the inside of the area 51B is a variable. Simulations have been carried out on the fourth embodiment 4B by changing the refractive index n₄ in order to find light-quantity ratios. Results of the simulations are shown in table 5 given below. It is to be noted that the light-quantity ratios shown in table 5 have been obtained by setting the light quantity of the typical comparison display apparatus 3′ at 1.00. In addition, the refractive index n₂ of the second member 52 has been set at 1.61 whereas the refractive index n₁ of the first member 51A having a layer shape has been set at 1.806.

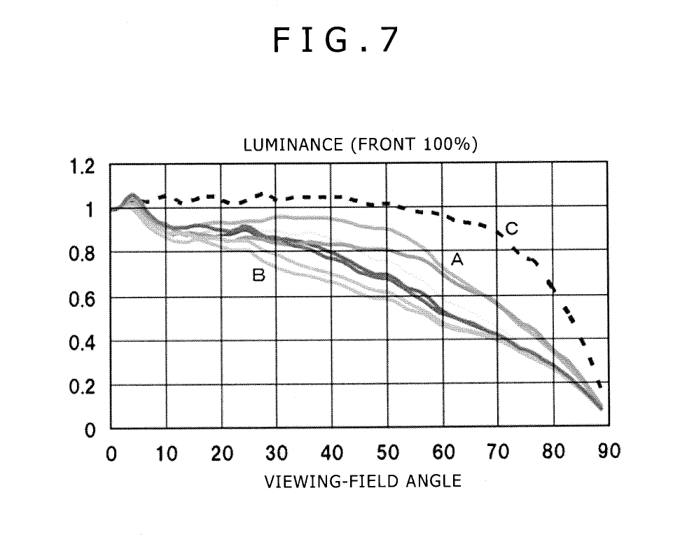

On top of that, relations between the viewing-field angle and the luminance relative value have also been examined. As explained earlier, the luminance relative value is a normalized value obtained by setting the luminance at a viewing-field angle of 0 in the typical comparison display apparatus 3′ at 1. Results of the examination are shown in FIG. 7. It is to be noted that, in FIG. 7, a curve A represents the relation for a case (22) shown in table 5 whereas a curve B represents the relation for a case (27) shown in the same table. On the other hand, a curve C represents the relation for the typical comparison display apparatus 3′. It is to be noted that parameters of the light reflecting layer employed in the organic EL display apparatus according to the fourth embodiment 4B are the same as the parameters shown in table 1 for the light reflecting layer employed in the organic EL display apparatus according to the third embodiment. In addition, the array of sub-pixels employed in the organic EL display apparatus according to the fourth embodiment 4B is the same as the array of sub-pixels employed in the organic EL display apparatus according to the third embodiment.

TABLE 5

| | | Refractive index n₄ | |
|---|---|---|---|
| | Refractive index n₃ | of sealing-material | |
| Case | of protection film 31 | layer 32 | Light-quantity ratio |
| (21) | 1.8 | 1.80 | 1.72 |
| (22) | 1.8 | 1.70 | 1.63 |
| (23) | 1.8 | 1.60 | 1.56 |
| (24) | 1.8 | 1.55 | 1.51 |
| (25) | 1.8 | 1.50 | 1.46 |
| (26) | 1.8 | 1.45 | 1.42 |
| (27) | 1.8 | 1.40 | 1.37 |

It is obvious from table 5 and FIG. 7 that, as the difference between the refractive index n₃ of the protection film 31 and the refractive index n₄ of the sealing-material layer 32 increases, the value of the light-quantity ratio decreases. On the other hand, the luminance relative value at a large viewing-field angle is larger than the luminance relative value at a viewing-field angle of 0 degrees. In addition, the light-quantity ratio for a case (26) shown in table 5 is smaller than 1.5. Thus, it is obvious that, with the refractive index n₃ of the protection film 31 set at 1.8, a value not smaller than 1.5 is desirable for the refractive index n₄ of the sealing-material layer 32. That is to say, it is desirable that the relation |n₃−n₄|≦0.3 is satisfied.

In addition, organic EL display apparatus according to the fourth embodiments 4C and 4D have the same parameters of the light reflecting layer as the parameters shown in table 1 for the light reflecting layer employed in the organic EL display apparatus according to the third embodiment. In addition, the array of sub-pixels employed in the organic EL display apparatus according to the fourth embodiments 4C and 4D is the same as the array of sub-pixels employed in the organic EL display apparatus according to the third embodiment. Simulations have been carried out on the fourth embodiments 4C and 4D by changing the diameter R₂ in order to find light-quantity ratios. Results of the simulations are shown in tables 6 and 7 given below. It is to be noted that the light-quantity ratios shown in tables 6 and 7 have been obtained by setting the light quantity of the typical comparison display apparatus 3′ at 1.00.

TABLE 6

| Case | R₂ (μm) | R₂/R₁ | Light-quantity ratio |
|---|---|---|---|
| (31) | 8.62 | 1.57 | 1.32 |
| (32) | 8.96 | 1.63 | 1.44 |
| (33) | 9.34 | 1.70 | 1.55 |
| (34) | 9.74 | 1.77 | 1.63 |
| (35) | 10.02 | 1.82 | 1.67 |
| (36) | 10.10 | 1.84 | 1.70 |
| (37) | 10.78 | 1.96 | 1.71 |

TABLE 7

| Case | R₂ (μm) | R₂/R₁ | Light-quantity ratio |
|---|---|---|---|
| (41) | 5.31 | 1.52 | 1.20 |
| (42) | 5.54 | 1.58 | 1.24 |
| (43) | 5.76 | 1.64 | 1.28 |
| (44) | 5.95 | 1.70 | 1.32 |
| (45) | 6.16 | 1.76 | 1.36 |
| (46) | 6.39 | 1.83 | 1.41 |
| (47) | 6.63 | 1.89 | 1.44 |
| (48) | 6.90 | 1.97 | 1.47 |

As is obvious from tables 6 and 7, as the value of the ratio R₂/R₁ increases, the value of the light-quantity ratio also increases but, as the value of the ratio R₂/R₁ approaches 2.00, the increase rate of the value of the light-quantity ratio decreases.

In addition, relations between the viewing-field angle and the luminance relative value have also been examined. As explained earlier, the luminance relative value is a normalized value obtained by setting the luminance at a viewing-field angle of 0 in the typical comparison display apparatus 3′ at 1. Results of the examinations indicate that, for ratios R₂/R₁ of 1.5 or smaller, as the viewing-field angle increases from −90 degrees, the luminance relative value also increases to approach a first maximum value. After the luminance relative value has attained the first maximum value, the luminance relative value decreases to attain a minimum value at a viewing-field angle of 0. After the luminance relative value has attained the minimum value, the luminance relative value increases again to attain a second maximum value. After the luminance relative value has attained the second maximum value, the luminance relative value decreases again.

As is obvious from the above results, it is desirable that the ratio R₂/R₁ is set at a value in a range of 1.6 to 2.0.

### Fifth Embodiment

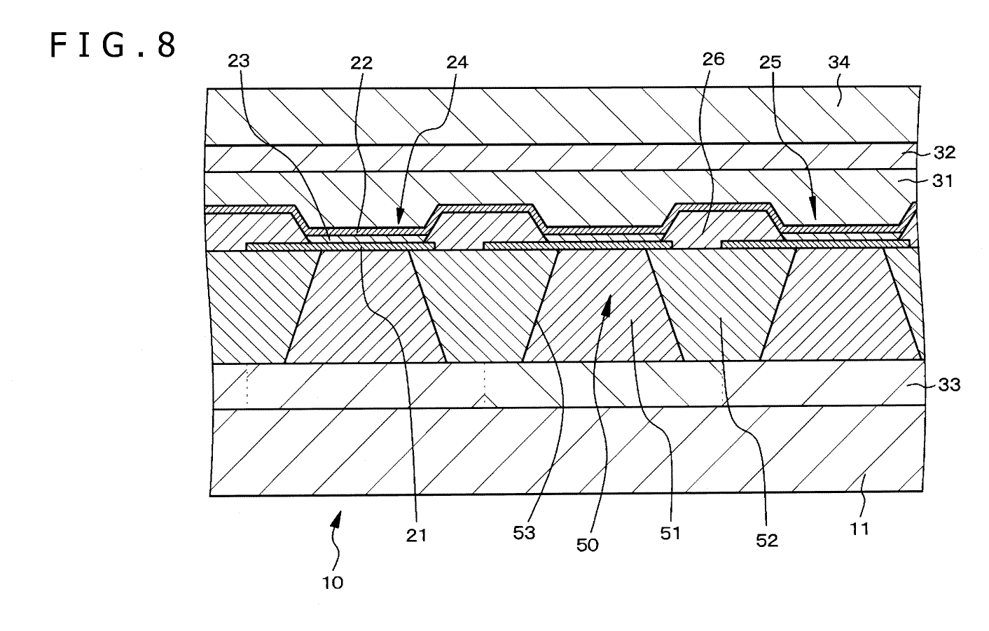

A fifth embodiment is also a modified version of the first embodiment. In the case of the fifth embodiment, however, light is output from the light emitting device 10 to the outside by way of the first substrate 11. That is to say, the organic EL display apparatus according to the fifth embodiment is an organic EL display apparatus of the bottom light emission type. FIG. 8 is a model diagram showing a portion of a cross section of the display apparatus according to the fifth embodiment. The display apparatus according to the fifth embodiment is an organic EL display apparatus adopting the active matrix system for displaying color images. It is to be noted that the array of sub-pixels is the same as that shown in FIG. 2A.

The first member 51 is created to have the shape of a headless circular cone (or a headless rotary body). The fifth embodiment satisfies relations given below. In the relations, reference notation R₁ denotes the diameter of the light incidence surface of the first member 51, reference notation R₂ denotes the diameter of the light exit surface of the first member 51, reference notation H denotes the height of the first member 51 whereas reference notation R₀ denotes the diameter of the light emitting section. In the case of the fifth embodiment, the light incidence surface of the first member 51 is a surface exposed to the second substrate 34 whereas the light exit surface of the first member 51 is a surface exposed to the first substrate 11.

R₁=2.3 μm

R₂=3.8 μm

R₁/R₂=0.61

H=1.5 μm

R₀=2.0 μm

0.5≦R₁/R₂≦0.8

0.5≦H/R₁≦2.0

It is to be noted that the cross-sectional shape of the inclined surface of the headless circular cone is a straight line. That is to say, the cross-sectional shape of the first member 51 is trapezoidal. By the way, the cross-sectional shape of the first member 51 is the shape of a cross section obtained by cutting the first member 51 over a virtual plane including the axis line of the first member 51.

In the case of the fifth embodiment, the second electrode 22 and the first electrode 21 are used as the anode and cathode electrodes respectively. The second electrode 22 is made of a light reflecting material or, more specifically, an Al—Nd alloy. On the other hand, the first electrode 21 is made of a light semi-transmitting material. To put it concretely, the first electrode 21 is made of a conductive material containing Mg (magnesium). To put it more concretely, the first electrode 21 is made of an Mg—Ag alloy having a thickness of 10 nm. The second electrode 22 is created by adoption of a film formation method with a particularly small energy of the film formation particle as is the case with the vacuum evaporation method. On the other hand, the first electrode 21 is created by adopting a combination of the vacuum evaporation method and the etching method.

In addition, the refractive indexes of the first electrode 21 and the second electrode 22, the average light reflection ratio of the first electrode 21 and the average light transmission ratio of the second electrode 22 have also been measured. Results of the measurements are the same as the first embodiment. When reading the measurement results of the first embodiment for the comparison purpose, however, the first electrode 21 should be interpreted as the second electrode 22 whereas the second electrode 22 should be interpreted as the first electrode 21.

In the case of the fifth embodiment, the first electrode 21 employed in the organic EL display apparatus is provided on the light reflecting layer 50 including the first member 51 and the second member 52. In addition, the light reflecting layer 50 covers an organic EL device driving section created on the first substrate 11. The organic EL device driving section itself is not shown in the figure. The organic EL device driving section is configured to include a plurality of TFTs. The TFTs are electrically connected to the first electrode 21 through contact plugs and wires. Also not shown in the figure, the contact plugs and the wires are provided on the second member 52. In some cases, the organic EL device driving section can also be provided over the light emitting section 24.

In the fifth embodiment, the protection film 31 and the sealing-material layer 32 are further provided on the light emitting section 24 in the same way as the first embodiment.

Simulations have been carried out on an organic EL display apparatus according to a fifth embodiment 5A and an organic EL display apparatus serving as a typical comparison display apparatus 5A in order to find radiation-angle distributions of the luminance. The organic EL display apparatus according to the fifth embodiment 5A is an organic EL display apparatus having a configuration and a structure which are devised for the fifth embodiment. In the organic EL display apparatus according to the fifth embodiment 5A,

the diameter R₁ is set at 2.3 μm;

the diameter R₂ is set at 3.8 μm;

the height H is set at 1.5 μm;

the angle of the inclined surface of the headless circular cone shape of the first member 51 is set at 63 degrees;

the thickness of the protection film 31 is set at 3.0 μm;

the thickness of the sealing-material layer 32 is set at 10 μm;

the thickness of the color filter 33 is set at 2.0 μm; and

the diameter of the light emitting section 24 or, to put it concretely, the diameter of the first electrode 21 is set at 2.0 μm.

The organic EL display apparatus serving as a typical comparison display apparatus 5A has a configuration and a structure which are identical with those of the organic EL display apparatus according to the fifth embodiment 5A except that the organic EL display apparatus serving as the typical comparison display apparatus 5A is provided with an SiO₂ layer replacing the light reflecting layer 50. Results of the simulations indicate that, in a range of radiation angles of ±10 degrees, the luminance efficiency of the organic EL display apparatus according to the fifth embodiment 5A is 2.2 times the luminance efficiency of the typical comparison display apparatus 5A whereas the driving current density of the organic EL display apparatus according to the fifth embodiment 5A is 0.4 times the driving current density of the typical comparison display apparatus 5A. In addition, if it is assumed that the color filter is shifted in the horizontal direction by 0.3 μm, the luminance efficiency of the organic EL display apparatus according to the fifth embodiment 5A is 2.3 times the luminance efficiency of the typical comparison display apparatus 5A, the driving current density of the organic EL display apparatus according to the fifth embodiment 5A is 0.5 times the driving current density of the typical comparison display apparatus 5A whereas the mixed-color ratio of the organic EL display apparatus according to the fifth embodiment 5A is 1.3%.

Also in the case of the organic EL display apparatus according to the fifth embodiment 5, the value of the refractive index n₁ of the first member 51 as well as the difference between the refractive index n₁ of the first member 51 and the refractive index n₂ of the second member 52 are prescribed in advance. Thus, it is possible to reliably reflect at least part of light propagating through the first member 51 on the surface of the second member 52 facing the first member 51, that is, on the boundary face between the first member 51 and the second member 52 even without providing a light reflecting member or the like. In addition, it is also possible to reliably prevent light emitted by the light emitting device 10 from being completely reflected by the first member 51. On top of that, it is also possible to attain all objectives including reduction of a driving current density to a value not greater than ½ times that of the existing organic EL display apparatus, enhancement of a luminance efficiency to a value not smaller than two times that of the existing organic EL display apparatus and reduction of a mixed-color ratio to a value not larger than 3%.

It is to be noted that the structure of the organic EL display apparatus according to the fifth embodiment can be applied to the organic EL display apparatus according to the third embodiment in order make use of the organic EL display apparatus according to the fifth embodiment in a TV receiver. In this case, in the same way as the third embodiment, a plurality of light emitting devices 10 are collected to form one sub-pixel.

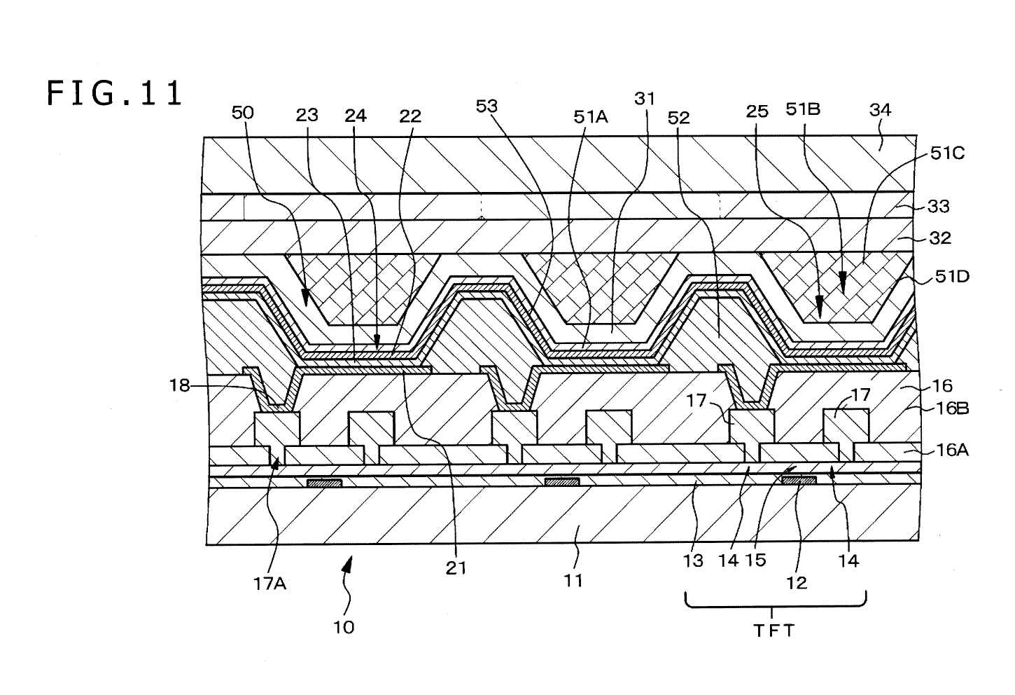

The present disclosure has been explained so far by describing preferred embodiments. However, implementations of the present disclosure are by no means limited to the preferred embodiments. That is to say, elements explained in the descriptions are typical. In other words, the elements can be modified. The elements include the organic EL display apparatus according to the embodiments, a configuration and a structure which are adopted by each of the organic EL display apparatus as well as materials used for making the organic EL display apparatus and the organic EL devices. For example, as shown in FIG. 11 which is a model diagram showing a portion of a cross section of a typical modified version obtained by modifying the display apparatus according to the fourth embodiment, a high refraction index area 51C having a refraction index n₅ higher than the refractive index n₃ of the protection film 31 can be provided instead of extending a portion of the sealing-material layer 32 to the inside of the area 51B. Thus, light propagating from the protection film 31 to the high refraction index area 51C collides with an inclined area 51D which is the boundary face between the protection film 31 and the high refraction index area 51C. Most of the light colliding with the inclined area 51D is returned to the high refraction index area 51C. As a result, it is possible to further improve the efficiency of fetching light from the light emitting device to the outside. It is to be noted that, for example, a condition of satisfying the following relation is desirable:

(n₅−n₃)≧0.3

It is also to be kept in mind that the present disclosure can also be realized into the following implementations:

1. A display apparatus including:

(A) a first substrate on which a plurality of light emitting devices each having a laminated stack including a first electrode, a light emitting section configured to have an organic layer including a light emitting layer and a second electrode are created; and

(B) a second substrate provided over the second electrode, wherein:

the first substrate is provided with a light reflecting layer including a first member for propagating light emitted by the light emitting device and outputting the light to the outside and a second member used for filling up a space between the first members;

the relations 1.1≦n₁≦1.8 hold true where reference notation n₁ denotes the refractive index of the first member;

the relation (n₁−n₂)≧0.2 holds true where reference notation n₂ denotes the refractive index of the second member; and

at least part of light propagating through the first member is reflected by a surface of the second member facing the first member or by a boundary face between the first member and the second member.

2. The display apparatus according to implementation 1 wherein the light emitting device and the first member are brought into contact with each other.

3. The display apparatus according to implementation 1 or 2 wherein light emitted by the light emitting devices is output to the outside by way of the second substrate.

4. The display apparatus according to implementation 3, the display apparatus further including

a protection film and a sealing-material layer on the light reflecting layer, wherein

the relation |n₃−n₄|≦0.3 holds true where reference notations n₃ and n₄ denote the refractive indexes of the protection film and the sealing-material layer respectively.

5. The display apparatus according to implementation 3 or 4 wherein the quantity of light emitted by the light emitting device and output to the outside through the first and second members has a value in a range of 1.5 to 2.0 where the value 1.0 is taken as the quantity of light emitted from the center of the light emitting device.

6. The display apparatus according to any one of implementations 3 to 5 wherein the second substrate is provided with a color filter.

7. The display apparatus according to any one of implementations 1 to 6 wherein a pixel is configured from one light emitting device.

8. The display apparatus according to implementation 7 wherein the first member has the shape of a headless circular cone satisfying the following relations:

0.5≦R₁/R₂≦0.8 and

0.5≦H/R₁≦2.0

where reference notation R₁ denotes the diameter of the light incidence surface of the first member, reference notation R₂ denotes the diameter of the light exit surface of the first member whereas reference notation H denotes the height of the first member.

9. The display apparatus according to any one of implementations 1 to 6 wherein a pixel is configured from a collection of a plurality of the light emitting devices.

10. The display apparatus according to implementation 9 wherein the first member has the shape of a headless circular cone satisfying the following relations:

0.5≦R₁/R₂≦0.8 and

0.5≦H/R₁≦2.0

where reference notation R₁ denotes the diameter of the light incidence surface of the first member, reference notation R₂ denotes the diameter of the light exit surface of the first member whereas reference notation H denotes the height of the first member.

11. The display apparatus according to any one of implementations 1 to 10 wherein:

the first member is made of Si₁₋ₓNₓ, ITO, IZO, TiO₂, Nb₂O₅, a polymer containing Br (bromine), a polymer containing S (sulfur), a polymer containing Ti (titan) or a polymer containing Zr (zirconium); and

the second member is made of SiO₂, MgF, LiF, polyimide resin, acryl resin, fluorine resin, silicon resin, a fluorine-series polymer or a silicon-series polymer.

12. A method for manufacturing a display apparatus including:

(A) a first substrate on which a plurality of light emitting devices each having a laminated stack including a first electrode, a light emitting section configured to have an organic layer including a light emitting layer and a second electrode are created; and

(B) a second substrate provided over the second electrode, wherein:

the first substrate is provided with a light reflecting layer including a first member for propagating light emitted by the light emitting device and outputting the light to the outside and a second member used for filling up a space between the first members; and

at least part of light propagating through the first member is reflected by a surface of the second member facing the first member or by a boundary face between the first member and the second member,

the manufacturing method including:

creating an inter-layer insulation layer on the first substrate and creating the first electrode on the inter-layer insulation layer; then

creating a second-member configuration layer on the first electrode and the inter-layer insulation layer and subsequently obtaining the second member having an aperture with an inclined slope plane by selectively removing the second-member configuration layer on the first electrode; then

creating the light emitting section and the second electrode over the slope plane of the aperture from a position above the first electrode exposed to the bottom of the aperture; and then creating the first member on the second electrode.

13. A method for manufacturing a display apparatus including

(A) a first substrate on which a plurality of light emitting devices each having a laminated stack including a first electrode, a light emitting section configured to have an organic layer including a light emitting layer and a second electrode are created, and

(B) a second substrate provided over the second electrode, wherein

the first substrate is provided with a light reflecting layer including a first member for propagating light emitted by the light emitting device and outputting the light to the outside and a second member used for filling up a space between the first members, and

at least part of light propagating through the first member is reflected by a surface of the second member facing the first member or by a boundary face between the first member and the second member,

the manufacturing method including:

preparing a stamper having a shape complementary to the first member;

applying a resin material to a support substrate; then

obtaining a resin-material layer having protrusions by removing the stamper after creating the resin material by making use of the stamper; then

flattening tips of the protrusions of the resin-material layer and then filling up spaces between the protrusions with a bonding-agent layer; and then

peeling off the resin-material layer from the support substrate and bonding the bonding-agent layer and the first substrate together in order to obtain the light reflecting layer configured from the second member including the bonding-agent layer and from the first member including the resin-material layer.

Moreover, the present disclosure can also be realized into the following implementations:

1. A display device comprising:

a plurality of light emitting devices formed on a substrate;
a plurality of first members corresponding to the light emitting devices and formed directly on a portion of the respective light emitting device; and
a plurality of second members formed in areas between adjacent first members,
wherein the first members and the second members are configured to reflect and guide at least a portion of light emitted from the light emitting sections through the first members.

2. The display device according to implementation 1,

wherein at least one light emitting device includes a first electrode, a second electrode, and a light emitting layer formed between the first and second electrodes, and
wherein the first members are formed directly on the second electrodes of the respective light emitting devices.

3. The display device according to implementation 2, wherein the light emitting layer is formed on the first electrodes and on the second members.

4. The display device according to implementation 3, wherein the first electrodes are made of a light reflecting material, and the second electrodes are made of an at least partially transparent material.

5. The display device according to implementation 1,

wherein at least one light emitting device includes a first electrode, a second electrode, and a light emitting layer formed between the first and second electrodes, and

wherein the first members are formed directly on the first electrodes of the respective light emitting devices, and are formed between the first electrodes and the substrate.

6. The display device according to implementation 5, wherein the second electrodes are made of a light reflecting material, and the first electrodes are made of an at least partially transparent material.

7. The display device according to implementation 1, wherein a value of a refractive index n₁ of the first members is different than a value of a refractive index n₂ of the second members.

8. The display device according to implementation 7, wherein the refractive index n₁ of the first members and the refractive index n₂ of the second members satisfy the following relationships:

1.1≧n₁≧1.8; and

(n₁−n₂)≧0.2.

9. The display device according to implementation 1, wherein a boundary face between the first members and the second members functions as a light reflector.

10. The display device according to implementation 1, wherein at least one layer is formed between the first members and the second members.

11. The display device according to implementation 10, wherein at least an electrode and a light emitting layer of the light emitting devices are formed between the first members and the second members.

12. The display device according to implementation 1, wherein the first members have a truncated conical shape.

13. The display device according to implementation 12, wherein the shape of the first members satisfies the following relationships:

0.5≦R₁R₂≦0.8; and

0.5≦H/R₁≦2.0,

wherein R₁ is a diameter of a light incident surface of the first member, R₂ is a diameter of a light exiting surface of the first member, and H is a height of the first member.

14. The display device according to implementation 1, wherein the first member comprises SiO₂ and the second member comprises SiN.

15. An electronic apparatus comprising:

a display device including

a plurality of light emitting devices formed on a substrate,

a plurality of first members corresponding to the light emitting devices and formed directly on a portion of the respective light emitting device, and

a plurality of second members formed in areas between adjacent first members,

wherein the first members and the second members are configured to reflect and guide at least a portion of light emitted from the light emitting sections through the first members.

16. A method of manufacturing a display device, the method comprising:

forming a plurality of light emitting devices on a substrate;

forming a plurality of first members corresponding to the light emitting devices directly on a portion of the respective light emitting device; and

forming a plurality of second members formed in areas between adjacent first members,

wherein the first members and the second members are configured to reflect and guide at least a portion of light emitted from the light emitting sections through the first members.

17. A display device comprising:

a plurality of light emitting devices formed on a substrate;

a plurality of first members corresponding to the light emitting devices, each first member formed over a respective one of the light emitting devices; and

a plurality of second members formed in areas between adjacent first members,

wherein a value of a refractive index n₁ of the first members is different than a value of a refractive index n₂ of the second members.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The application is claimed as follows:

1. A display device comprising:
a plurality of light emitting devices formed on a substrate;
a plurality of first members corresponding to the light emitting devices and formed directly on a portion of the respective light emitting device; and
a plurality of second members formed in areas between adjacent first members,
wherein the first members and the second members are configured to reflect and guide at least a portion of light emitted from the light emitting sections through the first members.

2. The display device according to claim 1,
wherein at least one light emitting device includes a first electrode, a second electrode, and a light emitting layer formed between the first and second electrodes, and
wherein the first members are formed directly on the second electrodes of the respective light emitting devices.

3. The display device according to claim 2, wherein the light emitting layer is formed on the first electrodes and on the second members.

4. The display device according to claim 3, wherein the first electrodes are made of a light reflecting material, and the second electrodes are made of an at least partially transparent material.

5. The display device according to claim 1,
wherein at least one light emitting device includes a first electrode, a second electrode, and a light emitting layer formed between the first and second electrodes, and
wherein the first members are formed directly on the first electrodes of the respective light emitting devices, and are formed between the first electrodes and the substrate.

6. The display device according to claim 5, wherein the second electrodes are made of a light reflecting material, and the first electrodes are made of an at least partially transparent material.

7. The display device according to claim 1, wherein a value of a refractive index n₁ of the first members is different than a value of a refractive index n₂ of the second members.

8. The display device according to claim 7, wherein the refractive index n₁ of the first members and the refractive index n₂ of the second members satisfy the following relationships:
1.1≦n₁≦1.8; and
(n₁−n₂)≧0.2.

9. The display device according to claim 1, wherein a boundary face between the first members and the second members functions as a light reflector.

10. The display device according to claim 1, wherein at least one layer is formed between the first members and the second members.

11. The display device according to claim 10, wherein at least an electrode and a light emitting layer of the light emitting devices are formed between the first members and the second members.

12. The display device according to claim 1, wherein the first members have a truncated conical shape.

13. The display device according to claim 12, wherein the shape of the first members satisfies the following relationships:
0.5≦R₁R₂≦0.8; and
0.5≦H/R₁≦2.0,
wherein R₁ is a diameter of a light incident surface of the first member, R₂ is a diameter of a light exiting surface of the first member, and H is a height of the first member.

14. The display device according to claim 1, wherein the first member comprises SiO₂ and the second member comprises SiN.

15. An electronic apparatus comprising:
a display device including
a plurality of light emitting devices formed on a substrate,
a plurality of first members corresponding to the light emitting devices and formed directly on a portion of the respective light emitting device, and
a plurality of second members formed in areas between adjacent first members,
wherein the first members and the second members are configured to reflect and guide at least a portion of light emitted from the light emitting sections through the first members.

16. A method of manufacturing a display device, the method comprising:
forming a plurality of light emitting devices on a substrate;
forming a plurality of first members corresponding to the light emitting devices directly on a portion of the respective light emitting device; and
forming a plurality of second members formed in areas between adjacent first members,
wherein the first members and the second members are configured to reflect and guide at least a portion of light emitted from the light emitting sections through the first members.

17. A display device comprising:
a plurality of light emitting devices formed on a substrate;
a plurality of first members corresponding to the light emitting devices, each first member formed over a respective one of the light emitting devices; and
a plurality of second members formed in areas between adjacent first members,
wherein a value of a refractive index n₁ of the first members is different than a value of a refractive index n₂ of the second members.
